(19) United States
(12) Patent Application Publication
(10) Pub. No.: US 2023/0178146 A1
(43) Pub. Date: Jun. 8, 2023

(54) APPARATUS AND METHOD FOR CHANGING THE FUNCTIONALITY OF AN INTEGRATED CIRCUIT USING CHARGE TRAP TRANSISTORS

(71) Applicant: THE REGENTS OF THE UNIVERSITY OF CALIFORNIA, Oakland, CA (US)

(72) Inventors: Sepideh NOURI, Los Angeles, CA (US); Subramanian IYER, Los Angeles, CA (US)

(73) Assignee: THE REGENTS OF THE UNIVERSITY OF CALIFORNIA, Oakland, CA (US)

(21) Appl. No.: 17/916,015

(22) PCT Filed: Mar. 30, 2021
(86) PCT No.: PCT/US2021/024952

§ 371 Date: Sep. 29, 2022

Related U.S. Application Data
(60) Provisional application No. 63/002,989, filed on Mar. 31, 2020.

(51) Int. Cl. G11C 11/419

(52) U.S. Cl. CPC G11C 11/419

(57) ABSTRACT

A method for changing functionality of an integrated circuit or improving performance of an integrated circuit, may include changing a threshold voltage of at least one charge trap transistor (CTT) in a nonvolatile multi-time programmable fashion. The at least one CTT may be fabricated using a high-k dielectric material as a gate dielectric. In some embodiments, the threshold voltage of the at least one CTT may be changed by increasing or decreasing the threshold voltage.

### CROSS REFERENCE TO RELATED APPLICATIONS

This application claims the benefit of and priority to U.S. Provisional Patent Application No. 63/002,989, filed Mar. 31, 2020, the entire disclosures of each of which are incorporated herein by reference.

### TECHNICAL FIELD

The present embodiments relate generally to system and method for changing functionality of an integrated circuit using charge trap transistors (CTT), and more particularly to system and method for changing a threshold voltage of at least one CTT in a non-volatile multi-time programmable fashion.

### BACKGROUND

Process variation, mismatch, and temperature may negatively impact the yield and performance of integrated CMOS (Complementary Metal-Oxide-Semiconductor) circuits. This negative impact becomes more severe in smaller CMOS nodes (e.g. sub-32 nm nodes). The reduction in yield increases the cost of produced working chips. Improvements in compensating process variation, mismatch, and temperature in smaller CMOS nodes remain desired.

### SUMMARY

The present embodiments relate to system and method for changing functionality of an integrated circuit using charge trap transistors (CTT).

According to certain aspects, embodiments provide a method for changing functionality of an integrated circuit or improving performance of an integrated circuit. The method may include changing a threshold voltage of at least one charge trap transistor (CTT) in a non-volatile multi-time programmable fashion. The at least one CTT may be fabricated using a high-k dielectric material as a gate dielectric. In some embodiments, the threshold voltage of the at least one CTT may be changed by increasing or decreasing the threshold voltage.

### BRIEF DESCRIPTION OF THE DRAWINGS

These and other aspects and features of the present embodiments will become apparent to those ordinarily skilled in the art upon review of the following description of specific embodiments in conjunction with the accompanying figures, wherein:

FIG. 1 is a circuit diagram illustrating an example SRAM and an example sense amplifier according to some embodiments;

FIG. 2 is a diagram illustrating example control signals for a read operation of an example SRAM and an example sense amplifier according to some embodiments;

FIG. 3 is a diagram illustrating example voltage signals during two read operation cycles in an example SRAM and an example sense amplifier;

FIG. 4 is a diagram illustrating an example signal (e.g. voltage of SENSE-SENSE_B) during two read operation cycles in an example SRAM and an example sense amplifier;

FIG. 5 is a diagram illustrating an example impact of threshold voltage variability during two read operation cycles in an example SRAM and an example sense amplifier. This figure shows the voltage of SENSE-SENSE_B versus time by sweeping Vth mismatch between two SA pull-down NFETs;

FIG. 6A, FIG. 6B and FIG. 6C illustrate an example of threshold voltage distributions in transistors of sense amplifiers with different widths (widths are 80 nm, 160 nm, and 320 nm, respectively. Gate length is 20 nm in all three figures);

FIG. 7 is a circuit diagram illustrating an example sense amplifier with a charge trap transistor (CTT) according to some embodiments;

FIG. 8A and FIG. 8B are circuit schematics illustrating an example of a precharge circuitry for a sense amplifier or a SRAM with a shunt device and an example of a precharge circuitry for a sense amplifier or a SRAM without a shunt device, respectively, according to some embodiments;

FIG. 9 is a diagram illustrating example BL−BLB voltage with (901) and without (902) precharge shunt device (see FIG. 8A and FIG. 8B, respectively) during two read operation cycles (see FIG. 3) in an example SRAM and sense amplifier, according to some embodiments;

FIG. 10 is a diagram illustrating example control signals for programming a CTT in an example sense amplifier according to some embodiments;

FIG. 11 is a circuit diagram illustrating an example ring oscillator with a charge trap transistor (CTT) according to some embodiments;

FIG. 12 is a diagram illustrating example values of oscillation frequencies as a result of changing threshold voltages using a CTT according to some embodiments;

FIG. 13A is a circuit diagram illustrating an example ring oscillator with a CTT in a programming mode according to some embodiments;

FIG. 13B is a circuit diagram illustrating an example ring oscillator with a CTT in an erase mode according to some embodiments;

FIG. 14 is a circuit diagram illustrating another example ring oscillator with a CTT according to some embodiments;

FIG. 15 is a circuit diagram illustrating an example ring oscillator with CTTs according to some embodiments;

FIG. 16A is a diagram illustrating example frequency values as a function of supply voltage in an example ring oscillator with CTTs according to some embodiments.

FIG. 16B is a diagram illustrating an example of effects of charge trapping on oscillation frequency in an example ring oscillator with CTTs according to some embodiments.

FIG. 16C is a diagram illustrating example oscillation frequency values as a function of VDD before and after programming an example ring oscillator with CTTs according to some embodiments.

FIG. 17A and FIG. 17B illustrate an example chip layouts of two ring oscillators with different number of stages according to some embodiments;

FIG. 18 is a flowchart illustrating an example methodology for changing functionality of an integrated circuit or improving performance of an integrated circuit using charge trap transistors (CTTs), according to some embodiments.

### DETAILED DESCRIPTION

According to certain aspects, embodiments in the present disclosure relate to techniques for changing functionality of an integrated circuit by changing a threshold voltage of charge trap transistors (CTT) in a non-volatile multi-time programmable fashion.

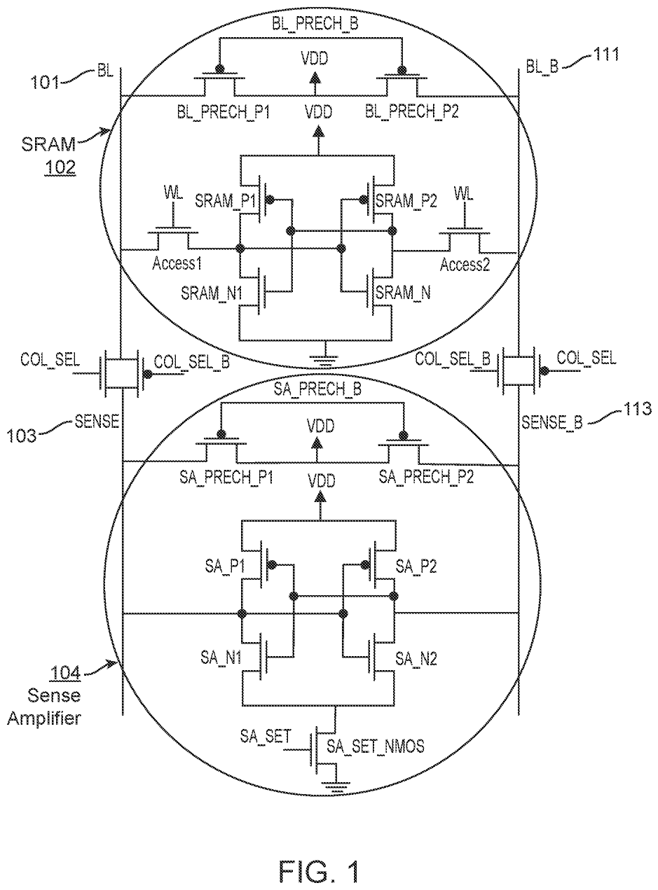

Before describing problems to be solved by embodiments of the present disclosure, an example impact of threshold voltage variability during read operations in an example SRAM and an example sense amplifier, and an example of threshold voltage distributions in transistors of sense amplifiers with different widths will be described with reference to FIG. 1 to FIG. 6C.

FIG. 1 is a circuit diagram illustrating an example static random access memory (SRAM) 102 and an example sense amplifier 104 according to some embodiments.

Referring to FIG. 1, the SRAM 102 may include a pair of P-channel metal-oxide-semiconductor (PMOS) transistors (SRAM_P1 and SRAM_P2), a pair of N-type metal-oxide-semiconductor (NMOS) transistors (SRAM_N1 and SRAM_N2), PMOS transistors (BL_PRECH_P1 and BL_PRECH_P2) to precharge a bitline BL (101) and a negative bitline BL_B (111), and NMOS transistors (Access1 and Access2) coupled to a wordline WL. A control signal BL_PRECH_B may be provided to respective gates of BL_PRECH_P1 and BL_PRECH_P2.

The sense amplifier (SA) 104 may include a pair of PMOS transistors (SA_P1 and SA_P2), a pair of NMOS transistors (SA_N1 and SA_N2), PMOS transistors (SA_PRECH_P1 and SA_PRECH_P2) to precharge a sense line SENSE (103) and a negative sense line SENSE_B (113), and an NMOS transistor (SA_SET_NMOS) coupled to SA_N1 and SA_N2. A control signal SA_SET may be provided to a gate of SA_SET_NMOS. A control signal SA_PRECH_B may be provided to respective gates of SA_PRECH_P1 and SA_PRECH_P2. The bitline BL (101) and the sense line SENSE (103) may be selectively coupled via a transmission gate controlled by a control signal COL_SEL and a negative control signal COL_SEL_B. Similarly, the negative bitline BL_B (111) and the negative sense line SENSE_B (113) may be selectively coupled via a transmission gate controlled by the control signal COL_SEL and the negative control signal COL_SEL_B.

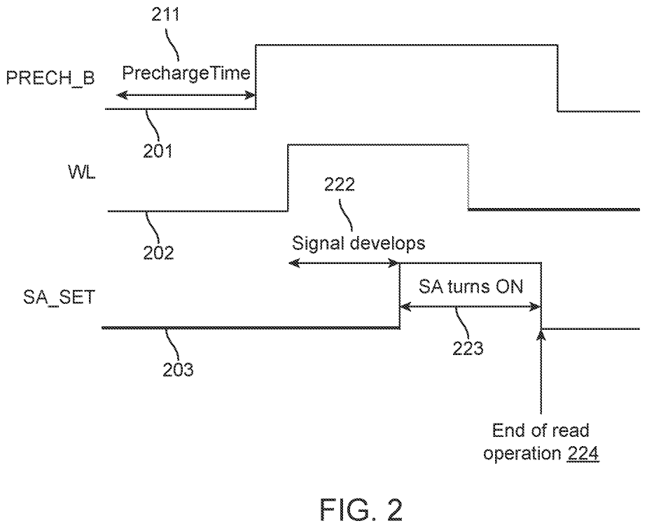

To read data stored in a memory cell (such as SRAM or DRAM), a sense amplifier (e.g., SA 104) amplifies a small differential signal generated on BL and BLB. Read operations using a sense amplifier will be described with reference to FIG. 2 to FIG. 4.

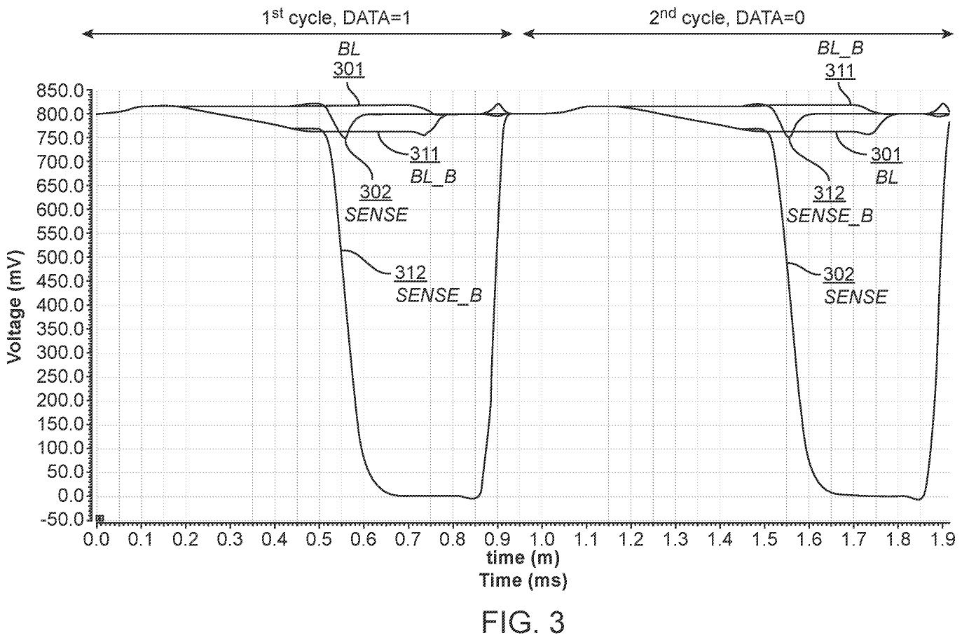

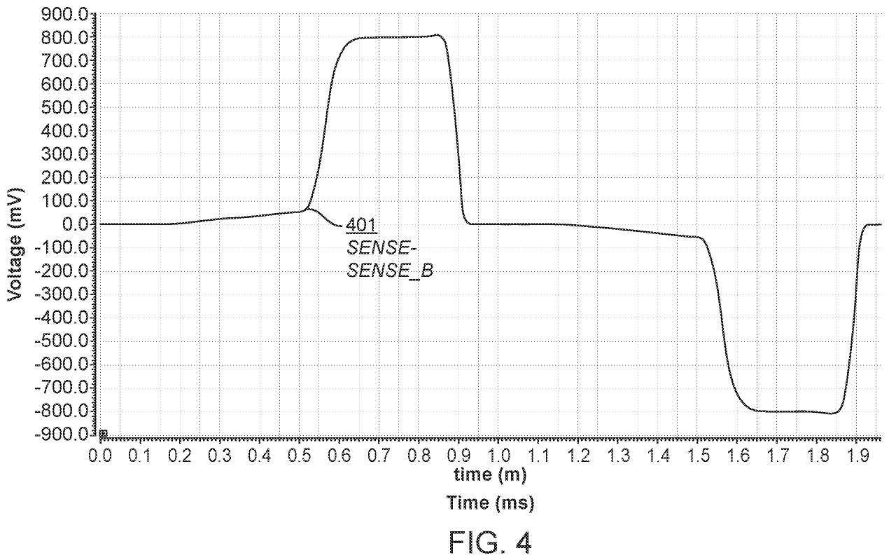

FIG. 2 is a diagram illustrating example control signals for a read operation of an example SRAM and an example sense amplifier. FIG. 3 is a diagram illustrating example voltage signals during two read operation cycles in an example SRAM and an example sense amplifier. FIG. 4 is a diagram illustrating an example signal (e.g., voltage of SENSE-SENSE_B) during two read operation cycles in an example SRAM and an example sense amplifier.

Referring to FIG. 2, a signal 201 indicates the control signal PRECH_B (which indicates both SA_PRECH_B and BL_PRECH_B signals; see FIG. 1) and a signal 203 indicates the control signal SA_SET (see FIG. 1). A signal 202 indicates a signal from the wordline WL (see FIG. 1). When a cycle of read operation begins, the sense line SENSE (103), the negative sense line SENSE_B (113), the bitline BL (101), and the negative bitline BL_B (111) may be precharged during a time period 211. During a time period 222, a signal (e.g., a small differential signal generated on BL and BL_B) may be developed. The SA 104 may turn on during a time period 223 which ends at a time 224. FIG. 3 shows a BL signal 301 (from the bitline BL), a BL_B signal 311 (from the negative bitline BL_B), a SENSE signal 302 (from the sense line SENSE), and a SENSE_B signal 312 (from the negative sense line SENSE_B) during two cycles of read operations in which data is logical “1” during the first cycle and data is logical “0” during the second cycle. FIG. 4 shows a (SENSE-SENSE_B) signal obtained by subtracting the SENSE_B signal 312 from the SENSE signal 302, which indicates logical “1” during the first cycle and logical “0” during the second cycle.

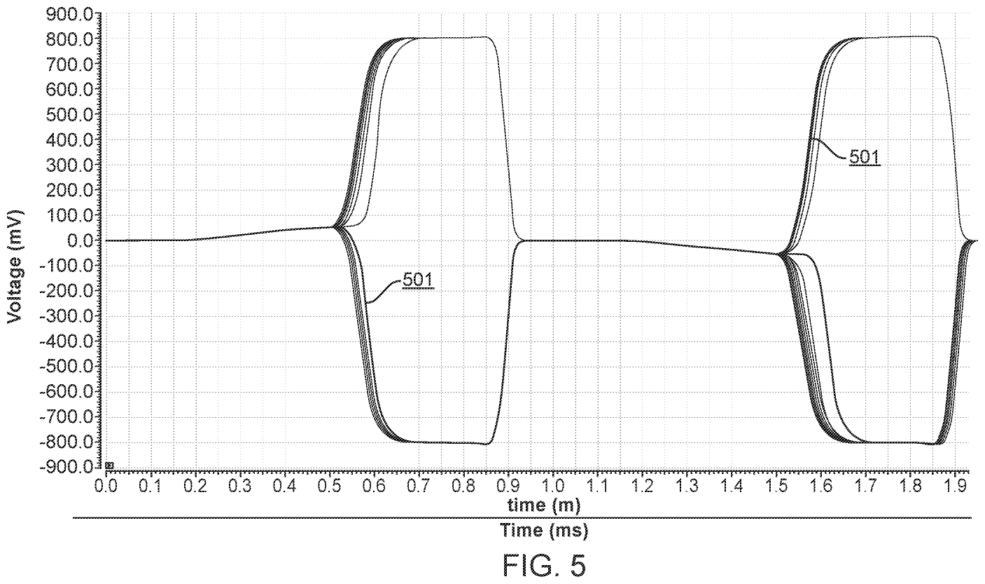

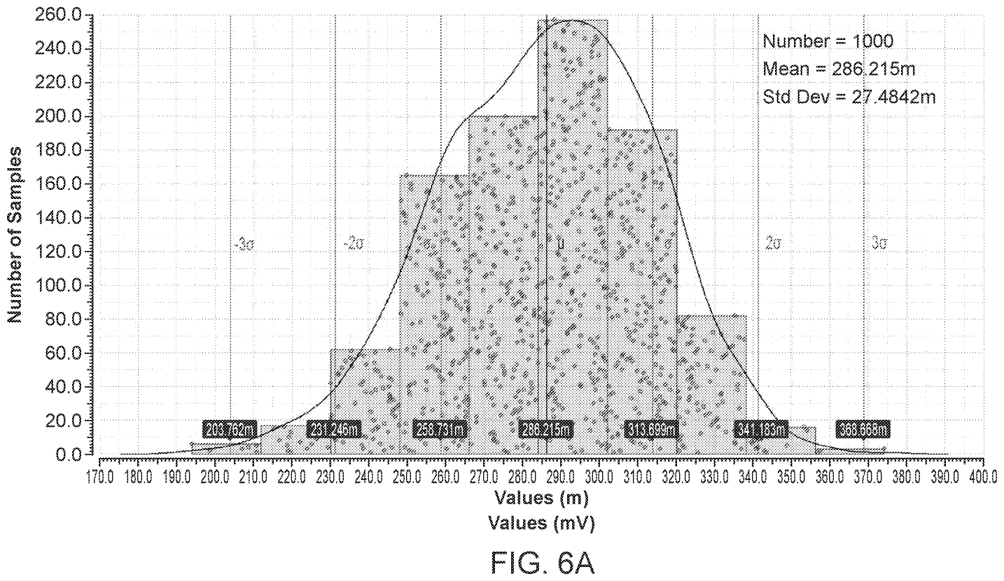

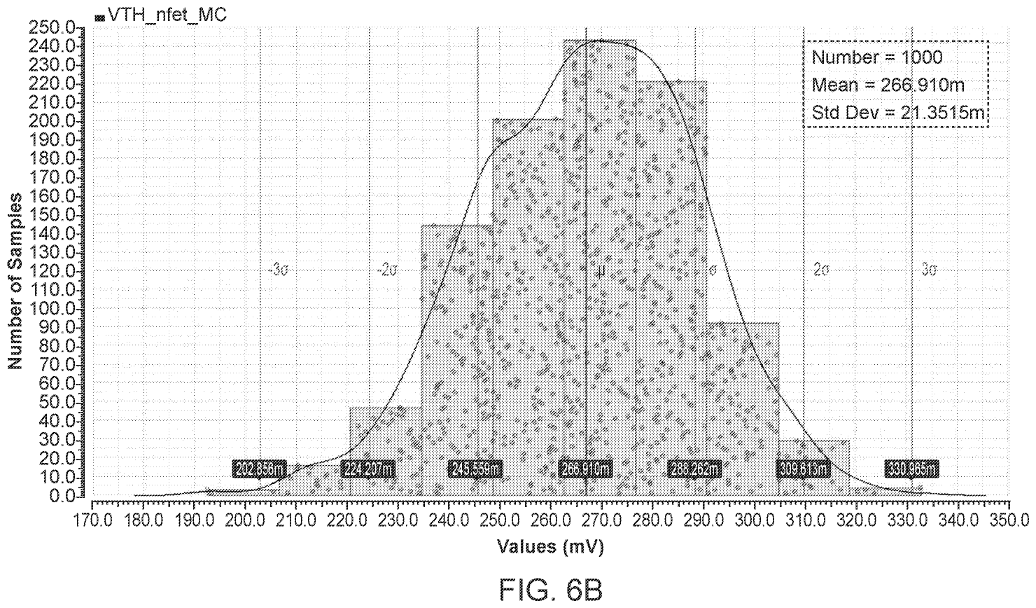

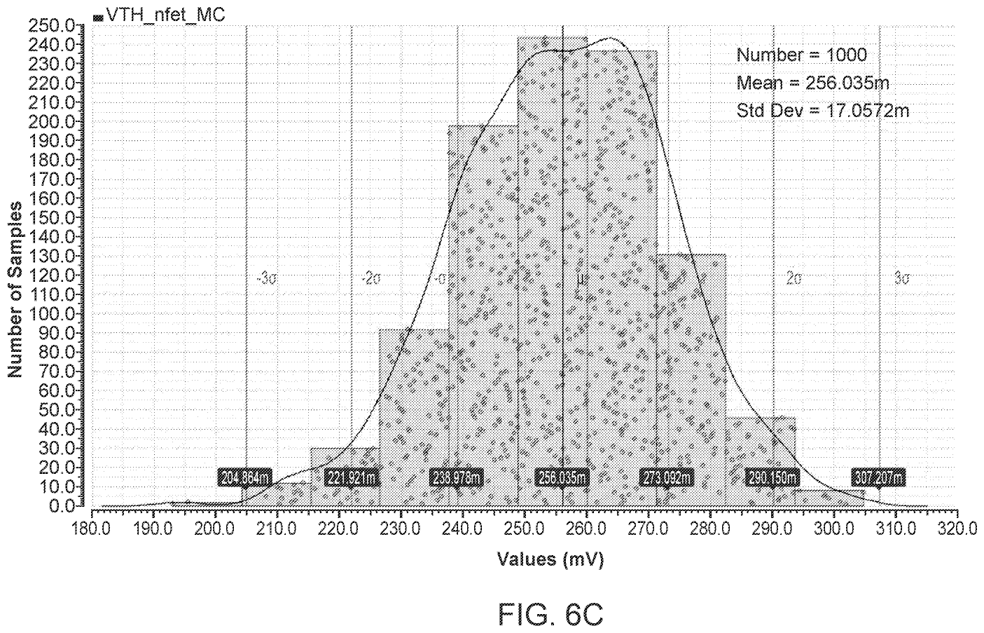

Since the differential signal on BL and BL_B is very small (e.g., less than or equal to 100 mV), a sense amplifier (e.g., the SA 104 in FIG. 1) may be very sensitive to a mismatch of threshold voltages (Vth) between the transistors on the right (e.g., SA_N2, SA_P2 in FIG. 1) and the transistors on the left (SA_N1, SA_P1 in FIG. 1) of the sense amplifier. The impact of such Vth mismatch will be described with reference to FIG. 5 to FIG. 6C.

FIG. 5 is a diagram illustrating an example impact of threshold voltage variability during two read operation cycles in an example SRAM and an example sense amplifier. This figure shows the voltage of SENSE-SENSE_B versus time by sweeping Vth mismatch between two SA pull-down NFETs. A sweeping region of threshold voltage mismatch (Δ_{Vth}) was set such that −100 mV<|Δ_{Vth}<+100 mV. A Monte Carlo analysis was conducted to estimate standard deviation of Vth for an NMOS transistor with W=100 nm, which was about 25 mV. The simulation results showed that read operations of the sense amplifiers fail in a (failure) region of threshold voltage mismatch (|Δ_{Vth}|) that is greater than 2*σ=50 mV, i.e., |Δ_{Vth}|>50 mV (Δ_{Vth}<−50 mV or Δ_{Vth}>+50 mV). In other words, 5% of sense amplifiers may fail. FIG. 5 shows an example (SENSE-SENSE_B) signal 501 obtained using a sense amplifier having transistors in the failure region of threshold voltage mismatch, obtained during two cycle read operations when data is logical “1” during the first cycle and data is logical “0” during the second cycle. The example (SENSE-SENSE_B) signal 501 indicates a failure of the sense amplifier (i.e., logical “0”) during the first cycle.

FIG. 6A, FIG. 6B and FIG. 6C illustrate an example of threshold voltage distributions in transistors of sense amplifiers with different widths in which widths are 80 nm, 160 nm, and 320 nm, respectively, and gate length is 20 nm in all three figures. A Monte Carlo analysis (simulation) was conducted to determine the Vth distribution for transistors of a sense amplifier. The simulation results showed that a standard deviation of threshold voltages (Vth), i.e., σ (Vth), depends on the size of a transistor. As shown in FIG. 6A, FIG. 6B and FIG. 6C, as the width of transistors becomes smaller, the standard deviation of Vth becomes larger. For example, transistors having the smallest width (80 nm) have the largest standard deviation of Vth of 27.48 mV, among the distributions shown in FIG. 6A, FIG. 6B and FIG. 6C.

Now, problems to be solved by embodiments of the present disclosure will be described.

Process variation, mismatch, and temperature may negatively impact the yield and performance of integrated CMOS (Complementary Metal-Oxide-Semiconductor) circuits. These may negatively impact functionality of circuits that are sensitive to process variation. For example, process variation in a differential sense amplifier causes the amplifier to read data incorrectly (e.g. reading “1” while the stored bit is “0” and vice versa) as shown in FIG. 5. Moreover, this negative impact becomes more severe in smaller CMOS nodes (e.g. sub-32 nm nodes). The reduction in yield increases the cost of produced working chips.

To solve these problems, according to certain aspects, embodiments in the present disclosure relate to methods for performing fine tuning and/or post-fabrication calibration by taking advantage of charge trap transistors (CTT)'s programmability. In some embodiments, this method for circuit calibration can be done in a post-fabrication phase. In some embodiments, the method may include changing a threshold voltage of transistors (e.g., MOSFET transistors) in advanced nodes, which typically use high-k gate dielectric (e.g. Hafnium dioxide (HfO₂)) as a gate dielectric material. In some embodiments, the threshold voltage of MOSFET transistors may be changed by trapping (or programming) or de-trapping (or erasing) charge in the gate dielectric material. The transistors that are used in this fashion are called Charge Trap Transistors (CTT). Any regular MOSFET with a high-k dielectric material (such as HfO₂) can be used as a CTT. High-k dielectric material is used because those materials can reliably trap/de-trap charges under certain biasing conditions. In some embodiments, a high-k gate dielectric material may be used in advanced nodes. When a CTT traps charges, trapped electrons create an electric field. This electric field impacts the behavior of a MOSFET as if its threshold voltage (Vth) has changed. In the case of an n-type FET transistor (NFET), Vth can be increased by trapping charge.

According to certain aspects, embodiments in the present disclosure relate to a method for increases a threshold voltage of an NMOS CTT by trapping charge. In some embodiments, trapping charge can be accomplished by applying a large positive gate-to-source voltage to a transistor while passing a high current between the drain and source of the transistor. During this process, hot electrons can be generated and trapped in the gate dielectric. In some embodiments, a large negative gate-to-source voltage can be applied to remove (or de-trap) the trapped charges. This negative voltage can electrostatically repel the electrons from the gate dielectric and reduce the trapped charge, resulting in lowering or decreasing the threshold voltage. A similar mechanism can be used in a PMOS CTT. This phenomenon of trapping or de-trapping charges is non-volatile in that the trapped charges will remain in the gate dielectric even after the chip is disconnected from a supply voltage/current.

In some embodiments, a post-fabrication non-volatile calibration may be performed on circuits with at least one CTT. In some embodiments, threshold voltages (Vth) of MOSFETs may be changed through CTT programming thereby alleviating some negative effects of process variation. In some embodiments, as an example of using CTT for post-fabrication calibration of circuits, a mismatch of a SRAM sense amplifier can be compensated or reduced using a CTT. As another example, the frequency of a ring oscillator can be adjusted using a CTT.

According to certain aspects, embodiments in the present disclosure relate to a method for calibrating an analog/mixed signal circuits (such as a SRAM, a SRAM sense amplifier, an analog amplifier, etc.) using the threshold voltage programmability of CTT transistors to maximize the yield of the circuits. For example, process variation in a differential sense amplifier may cause the amplifier to read data incorrectly (e.g. reading logical “1” while the stored bit is logical “0” and vice versa as shown in FIG. 5). In some embodiments, this mismatch may be resolved, compensated, removed or adjusted by fine-tuning the threshold voltage of transistors in a sense amplifier or in an SRAM, without increasing the size of the transistors to compensate for the mismatch. This reduction of the size of the sense amplifier can result in (A) faster SRAM read operation and (B) lower energy/bit in the read process.

According to certain aspects, embodiments in the present disclosure relate to a method for building a non-volatile SRAM using the threshold voltage programmability of CTT transistors. In some embodiments, asymmetry (in terms of amount of trapped charges in transistor's gate dielectric) can be added to the SRAM cell by trapping charge in the core of a SRAM. In this manner, when the SRAM loses power, it can keep its state. When the power is tuned back on, the SRAM can return to the original state due to the asymmetry introduced by trapped charges in CTT. This phenomenon is non-volatile, which can make the SRAM a non-volatile memory.

According to certain aspects, embodiments in the present disclosure relate to a method for improving the performance of analog or digital circuits by reducing the size of transistors using the threshold voltage programmability of CTT transistors. The reduction of the size of transistors can lead to a higher speed of operation. For example, in comparators of an Analog to Digital Converter (ADC), transistors can be made larger to reduce the effect of variations in the geometry due to the process variation and/or mismatch (see FIG. 6A to FIG. 6B). However, increasing the size of ADC may lead to the reduction of the speed of operation. In some embodiments, smaller transistors can be used in analog or digital circuits (e.g., an ADC) using the threshold voltage programmability of CTT transistors to increase a speed of operation, while compensating process variation and/or mismatch in the circuits using CTT programmability.

According to certain aspects, embodiments in the present disclosure relate to a method for changing the delay of a MOSFET CTT by changing its threshold voltage using the threshold voltage programmability of the MOSFET CTT. In some embodiments, an oscillation frequency of an oscillator can be varied by changing the delay of MOSFET devices in the oscillator. In some embodiments, a CTT can be used to adjust a propagation delay of signals in analog or digital circuits. For example, a CTT can be used to balance the delay of a clock tree or data paths of analog or digital circuits to minimize a clock skew or correct hold-time violations in the circuits.

According to certain aspects, embodiments in the present disclosure relate to a method for changing functionality of an integrated circuit or improving performance of an integrated circuit. The method may include changing a threshold voltage of at least one charge trap transistor (CTT) in a non-volatile multi-time programmable fashion. In some embodiments, the threshold voltage of the at least one CTT may be changed by increasing or decreasing the threshold voltage.

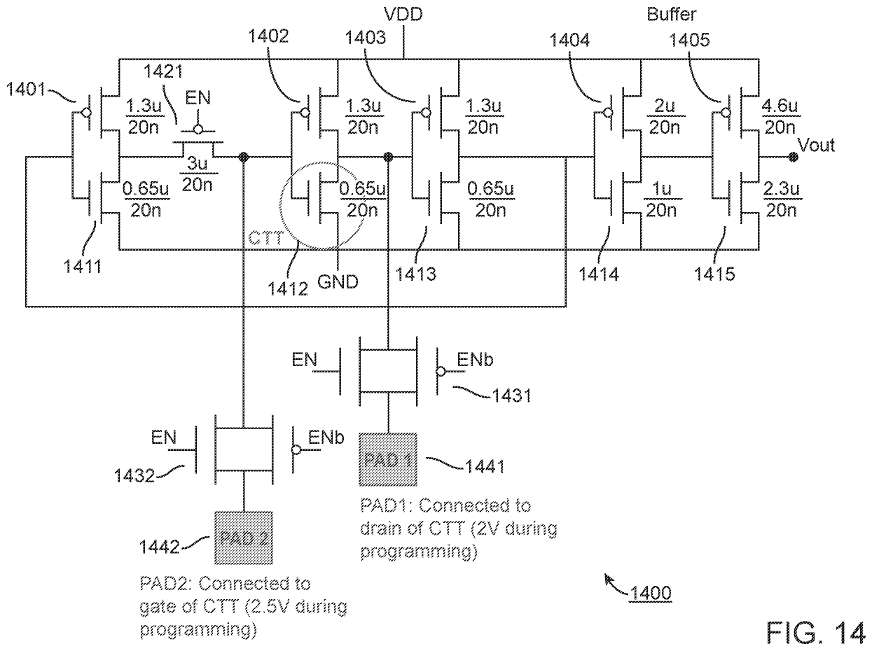

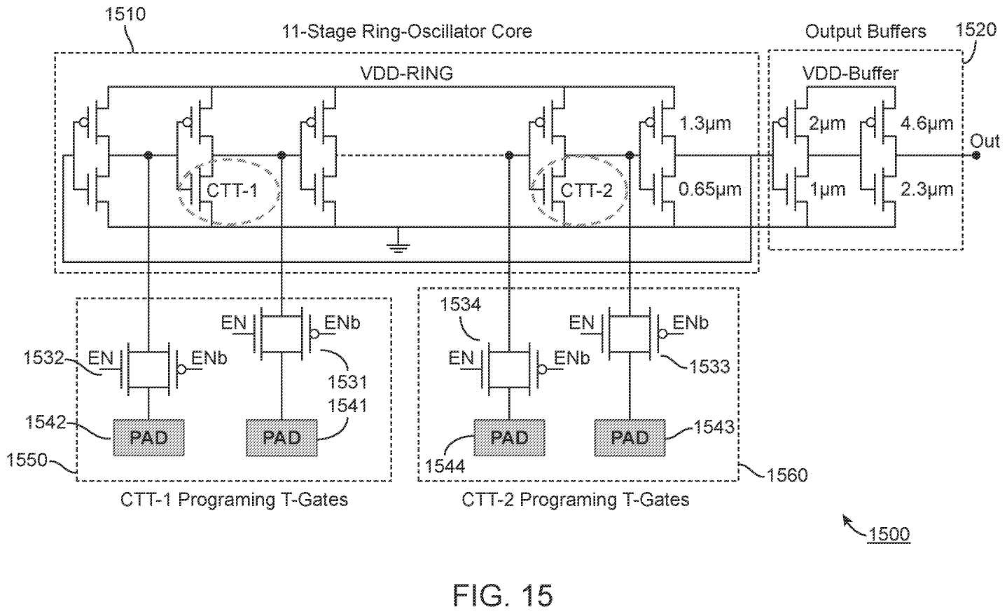

As noted above, process and parametric variation negatively impact the performance and yield of analog and digital circuits in advanced nodes. To alleviate this effect, embodiments in the present disclosure provide a technique to electrically adjust a threshold voltage of CMOS transistors in a post-fabrication setting in a non-volatile manner. This technique may utilize a self-heating assisted trapping of charge in high-k gate dielectric (e.g. HfOx) used in advanced CMOS nodes, and thereby does not require any extra fabrication step. In some embodiments, charge trapping may be used for wideband non-volatile frequency tuning of a ring oscillator. For example, the present disclosure demonstrates that the frequency of the ring oscillator can shift from 2075 MHz to 1746 MHz, when a supply voltage of 0.8V is used (see FIG. 15 and the description thereof). This technique can apply to non-volatile tuning, reconfiguration, and/or obfuscation of chips and IP (intellectual property) blocks, in which a chip can be fabricated, for example, in GlobalFoundries 22 nm Fully-Depleted Silicon-on-Insulator (FDSOI) CMOS process.

Moreover, as CMOS technology scales down to nanometer regime, process variation increases. This negatively impacts the performance of the circuits. For example, in a 22 nm CMOS node, one-sigma V_{TH} (threshold voltage) variation of the minimum size transistor is about 10%. Process variations may be compensated by employing different techniques such as increasing the device dimensions. However, increasing the device size increases the parasitic capacitance, reduces the switching speed, and increases the power consumption. This is particularly important in high-frequency circuits such as GHz oscillators or amplifiers. To compensate the effect of V_{TH} variation on the frequency of GHz oscillators and amplifiers, frequency tuning and calibration may be accomplished by means of switched-capacitor tuning, varactor tuning, or back-gate/body biasing. Unfortunately, none of these techniques are non-volatile and therefore the calibration information is lost if the chip loses power. To address this issue, embodiments in the present disclosure provide a technique that utilizes charge trapping to adjust V_{TH} and tune the frequency of an oscillator in a non-volatile fashion.

In some embodiments, any CMOS transistor that has high-k gate dielectric (e.g. HfOx) can trap electrons and be used to adjust V_{TH} and tune the frequency of an oscillator in a non-volatile fashion. CTT can trap and de-trap electrons multiple times (>10,000) under proper bias conditions. Electron trapping can increase V_{TH} of an NMOS, while controlled de-trapping reduces its V_{TH}. In some embodiments, a tuning circuit can be designed to demonstrate charge trapping, though de-trapping is possible with circuit modifications. PMOS transistors can exhibit the CTT effect, in some embodiments.

High-k gate dielectrics have oxygen vacancies that can trap electrons in the channel under certain biasing conditions. Charge trapping is an electrostatically driven phenomenon and a sufficiently large positive gate-to-channel voltage can attract electrons to the gate dielectric. In some embodiments, this process can be significantly enhanced by heating the device through passing a high current from drain to source (self-heating). The self-heating assisted charge trapping produces much more stable trapped charges that are not possible to achieve with a conventional Positive Bias Temperature Instability (PBTI) effect, because the elevated temperature produces increased trapping into deeper states in the dielectric.

The amount of shift in V_{TH} can be calculated based on the following equation:

ΔV_{TH}=ΔV_{TH-max}(1−e^{-(t/τ}^{₀}⁾^{^{β}}) (Equation 1)

In Equation 1, ΔV_{TH-max} represents a maximum amount of shift in V_{TH} that can be achieved through charge trapping process. Since, for a fixed device temperature, there are a finite number of traps in the gate dielectric, the amount of shift in V_{TH} saturates after these traps are filled. In Equation 1, τ₀ and β are fitting parameters used to model the exponential saturation behavior of the trap filling process as a function of time t. In some embodiments, β ranges from 0.25 to 0.5 by increasing the temperature of the device and τ₀ decreases from 10 s to 20 ms as a logarithmic function of temperature. ΔV_{TH-max}, itself is empirically shown to depend on the temperature T and gate bias voltage V_{G} according to the following equation:

$$Δ {V}_{TH - max} = {{de}^{gT} ( \frac{{V}_{G}}{{V}_{0}} )}^{m} \qquad ( Equation 2 )$$

where, in some embodiments, d˜100 nV, g˜0.02 K⁻¹, m˜7, and V₀=1V. Equation 2 indicates that ΔV_{TH-max} increases exponentially as a function of temperature and ΔV_{TH-max} increases with the gate bias.

In some embodiments, the charge trapping technique in 22 nm FDSOI process can shift the V_{TH} of an NMOS transistor by 360 mV, when a gate voltage of 2.2V and drain voltage of 1.1V is applied for 10 msec. In contrast with other methods of V_{TH} tuning such as body/back-gate biasing, the achieved shift in V_{TH} is non-volatile and can last over 10 years in elevated temperature of 85° C. Furthermore, CTT can be programmed and erased multiple times.

In some embodiments, the charge trapping technique can electrically tune the threshold voltage (Vth) of FETS in commercial 22 nm FDSOI and 14 nm bulk and SOI fin field-effect transistor (FinFET) processes to >150 mV with ˜10 mV precision using self-heating induced thermally assisted trapping (see Table 1). In some embodiments, trapping can be controlled by electrostatic injection and/or tunneling into the deeper gate dielectric traps via a high gate voltage in the presence of a self-heating drain current. De-trapping can be accomplished by merely reversing the gate voltage with no drain current necessary. At the device and array level, up to several thousand and several hundred programming and de-programming cycles can be performed with practically acceptable hysteresis, respectively. Temperature stability can be achieved to acceptable levels for digital memories up to 125° C. Since the CTT is fabricated in a commercial process with no new material or process modifications, there is no additional cost or process complexity and variability is comparable to a state-of-the-art commercial process. In some embodiments, digital one-time and multi-time programmable memory and analog in-memory computation (such as a multiply-and-accumulate engine for neural networks) can be built/performed using the CTT in advanced nodes from multiple fabs.

According to certain aspects, embodiments in the present disclosure provide reconfigurable analog and digital circuits for tuning and obfuscation purposes. In reconfigurable analog and digital circuits according to some embodiments, a threshold voltage (Vth) can be reconfigured on-chip oscillators, SRAM, and sense amplifiers. For example, by electrically controlling the Vth of a CTT NMOS used in a ring oscillator (RO), the effective delay of an inverter in RO can be changed and the oscillation frequency can be controlled. This technique can be expanded to more complex digital circuits and used for obfuscation purposes. For example, circuits can be designed to be either non-functional or marginally functional when the chip leaves foundry, but by post fab tuning, functionality can be restored. If large number of CTTs (around 32 to 64 CTTs) are used in a design, a complex combinatorial code can be created that will make it very difficult for someone to copy the layout and use it without knowing the right Vth values for those CTT devices required for chip functionality. In some embodiments, CTT devices can be used to perform self-balancing of an SRAM sense amplifier. In a normal sense amplifier, there is always a Vth mismatch between the transistors of the sense amplifier due to manufacturing variability or dopant fluctuation. This mismatch negatively impacts the operation of the sense amplifier. In some embodiments, a method can compensate for the effect of the Vth mismatch in a sense amplifier by trapping charges in the gate oxide of the transistors used in a sense amplifier. This method can improve the yield of SRAM memory chips by performing CTT-assisted self-healing. In some embodiments, by electrically controlling the Vth of CTT devices, the CTT devices can perform self-healing/self-reconfiguring in a robust and secure long-term manner.

According to certain aspects, embodiments in the present disclosure provide a method of controlled trapping/de-trapping of charges in CTT devices in a case where large transients or aging effects may increase the Vth of the transistors in advanced CMOS nodes that utilize high-k dielectric material as their gate oxide. The method can compensate the negative impact of maliciously induced transient or aging effects by de-trapping the charges from key transistors in the design, e.g., by de-trapping the charges in the high-k gate oxide. For example, the method can design circuits and intentionally induce large transients, measure the deterioration of the circuit, and then de-trap the charges from HfOx layer using a custom circuitry. In some embodiments, by de-trapping charges, the method can reduce the Vth of the transistors and bring their properties back to normal as much as possible. For example, after intentionally stressing the transistors to intensify the aging effects, the method can de-trap charges and bring the Vth of the transistors to their original value. In some embodiments, a circuit can be designed for obfuscation purposes. For example, the biasing voltages or the delay of a circuit can be intentionally set such that the chip will not function until the Vth of certain transistors is adjusted. When the chip returns from foundry, the Vth of those transistors can be adjusted by trapping charges to show that the chip becomes functional. This method can be served as a physical obfuscation using CTT devices.

According to certain aspects, embodiments in the present disclosure provide a method of circuit modification for obfuscation purpose. Obfuscation refers to changing the purpose of the circuit to thwart (frustrate, prevent, avoid, suppress, restrain, repress, inhibit or stop) security exposures. For example, at initial chip test the function of a circuit block (for example, one or more circuits, one or more ICs, one or more IC chips, one or more IP (intellectual property) blocks, or one or more electric devices) is represented by y=f(x), after a judicious threshold modification, the circuit block performs a different function y=f(x). Thus, if malicious actors intend to spy on the circuit function (say in the fab or at the assembly house), they will not be exposed to the true function of the circuit as it would have been changed by the user, after the chip has been integrated into the system, by modifying threshold voltages of one or more devices.

Embodiments in the present disclosure have at least the following advantages and benefits.

First, embodiments in the present disclosure can provide useful techniques for resolving or compensating or removing a mismatch in an integrated circuit (e.g., a mismatch of threshold voltages between transistors) by fine-tuning a threshold voltage of the integrated circuit (e.g., a sense amplifier in an SRAM) without increasing the size of the integrated circuit. In this manner, there is no need to increase the size of the sense amplifier to compensate the mismatch, thereby reducing the size of the sense amplifier size and achieving (A) a faster SRAM read operation and (B) a lower energy/bit in the read process.

Second, embodiments in the present disclosure can provide useful techniques for implementing a non-volatile SRAM that is superior to traditional non-volatile memories (such as flash memory) in terms of (A) having a lower write power consumption by programming the threshold voltage of CTT with a lower voltage (B) being fabricated with a standard CMOS process without requiring extra fabrication steps.

Third, embodiments in the present disclosure can provide useful techniques for improving performance of analog or digital circuits by reducing the size of transistors, which leads to a higher speed of operation.

Fourth, embodiments in the present disclosure can provide useful techniques for balancing the delay of a clock tree or data paths in analog or digital circuits to minimize the clock skew or correct hold-time violations.

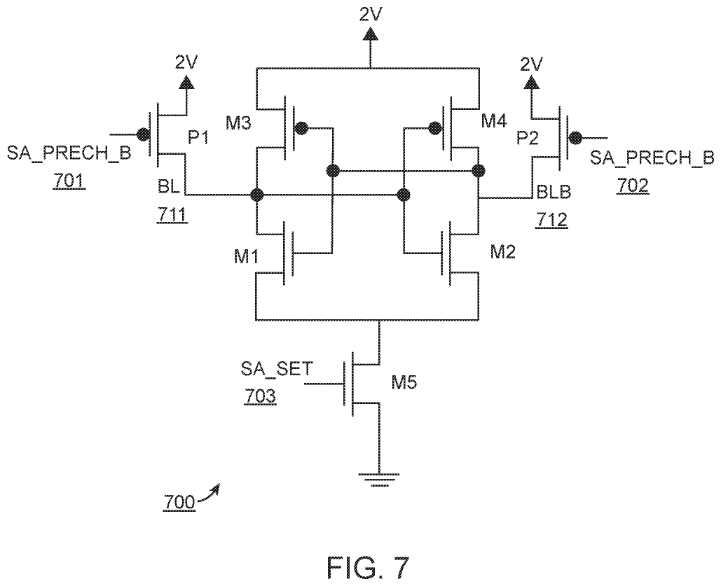

FIG. 7 is a circuit diagram illustrating an example sense amplifier with a charge trap transistor (CTT) according to some embodiments.

Referring to FIG. 7, a sense amplifier (SA) 700 may include a pair of PMOS transistors (M3 and M4), a pair of NMOS transistors (M1 and M2), a PMOS transistor P1 to precharge a bit line BL 711, and a PMOS transistor P2 to precharge a negative bit line BLB 712, and an NMOS transistor M5 coupled to M1 and M2. A control signal SA_SET may be provided to a gate of M5. A control signal SA_PRECH_B may be provided to respective gates of P1 and P2. In some embodiments, the NMOS transistor M2 is a CTT. In some embodiments, the SA 700 may include at least one CTT which is at least one of NMOS transistor or PMOS transistor. At least one of NMOS transistor or PMOS transistor is fabricated using a high-k dielectric material as a gate dielectric.

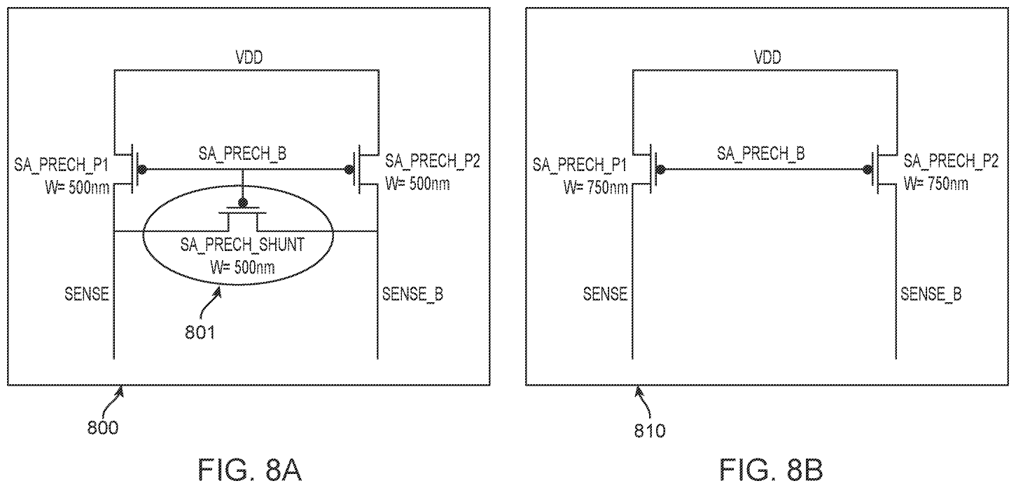

FIG. 8A and FIG. 8B are circuit schematics illustrating an example precharge circuitry with a shunt device and an example precharge circuitry without a shunt device, respectively, according to some embodiments. FIG. 8A shows a circuit schematic of a precharge circuitry in which a pre-charge shunt device 801 (SA_PRECH_SHUNT) with width of 500 nm is connected between the drains of the pair of PMOS transistors (SA_PRECH_P1 and SA_PRECH_P2). In some embodiments, as shown in FIG. 8A, the width of the PMOS pair is 500 nm and the width the shunt device is 500 nm, thereby the width of the precharge circuitry 800 is equal to 1500 nm. FIG. 8B shows a circuit schematic of a precharge circuitry 810 in which there is no such shunt device connected between the drains of the pair of PMOS transistors (SA_PRECH_P1 and SA_PRECH_P2). In some embodiments, as shown in FIG. 8B, the width of the PMOS pair is 750 nm, thereby the width of the precharge circuitry 810 is equal to 1500 nm. In some embodiments, the pre-charge shunt device 801 may be a PMOS transistor. A similar precharge circuitries, with or without a shunt device, may be used to precharge BL and BL_B.

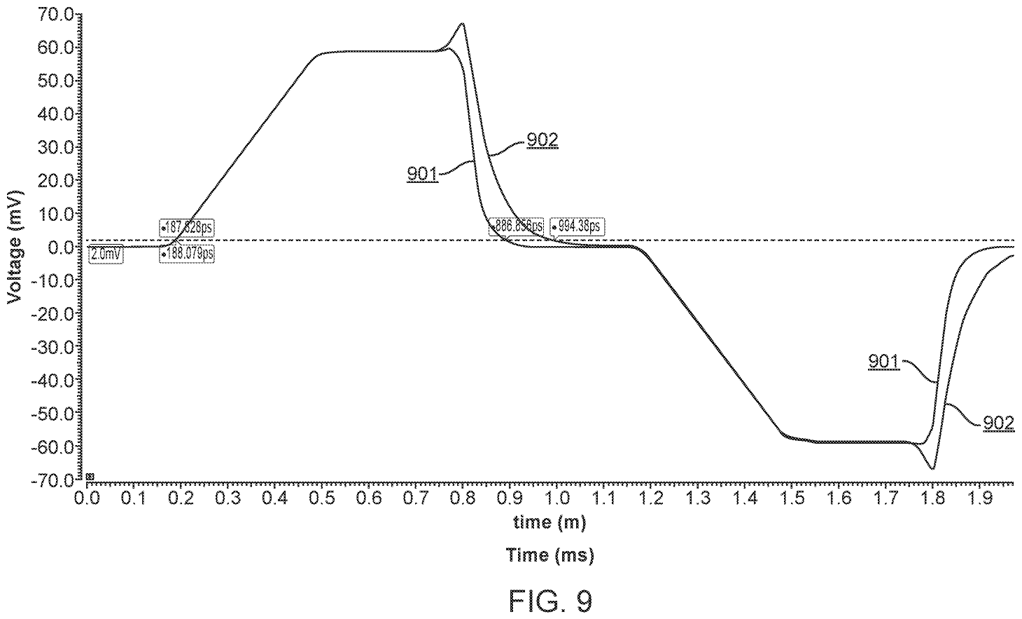

FIG. 9 is a diagram illustrating example BL−BLB voltage with (901) and without (902) precharge shunt device (see FIG. 8A and FIG. 8B, respectively) during two read operation cycles (see FIG. 3) in an example SRAM and sense amplifier, according to some embodiments. Referring to FIG. 9, a signal 901 indicates a (BL−BLB) signal obtained from the precharge circuitry 800 (with a pre-charge shunt device) in FIG. 8A during two cycles of read operations in which data is logical “1” during the first cycle and data is logical “0” during the second cycle. Similarly, a signal 902 indicates a (BL−BLB) signal from the precharge circuitry 810 (without a pre-charge shunt device) in FIG. 8B during two cycles of read operations in which data is logical “1” during the first cycle and data is logical “0” during the second cycle. As shown in FIG. 9, pre-charging with a pre-charge shunt device is performed faster than that without a pre-charge shunt device.

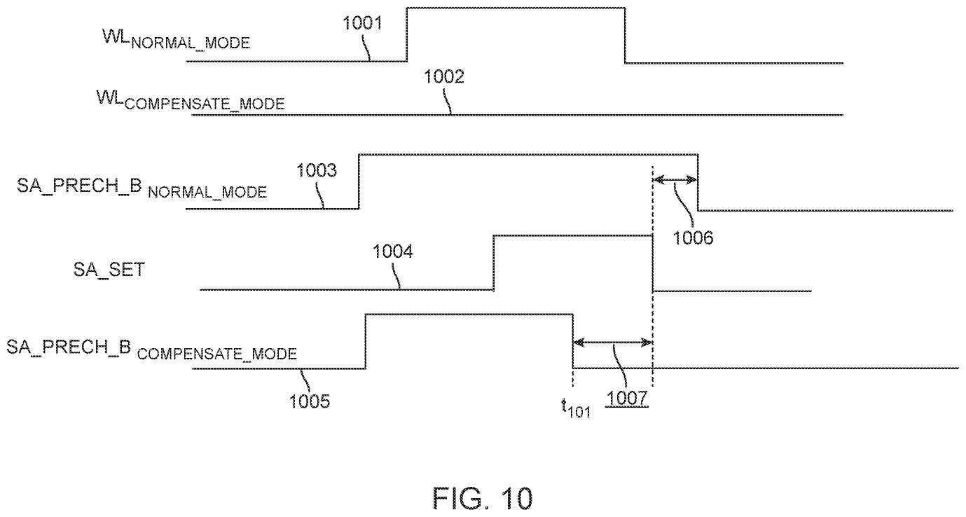

FIG. 10 is a diagram illustrating example control signals for programming a CTT in an example sense amplifier according to some embodiments. Referring to FIG. 10, a signal 1001 indicates a signal from a wordline WL in normal mode (denoted by WL_{NORMAL_MODE}) in a sense amplifier (e.g., the Sense Amplifier 104 see FIG. 1), and a signal 1002 indicates a signal from a wordline WL in compensate mode (denoted by WL_{COMPENSATE_MODE}) in the sense amplifier. In some embodiments, a sense amplifier may be diagnosed to determine there is a mismatch in the sense amplifier (e.g., a mismatch of threshold voltages between transistors of the amplifier). The sense amplifier may be set to compensate mode based on the result of the diagnosis. (e.g., when it is determined that there is a mismatch). To diagnose if the transistors of a sense amplifier have a Vth mismatch, SA may be turned on without giving any external signal (BL−BL_B=0V). In this case, SENSE and SENSE_B signals take a logical state based on the Vth mismatch of SA transistors, which is called the favorite state. This process may be repeated several times. If SA takes the same favorite state every time, it is determined that the transistors have Vth mismatch. It can be determined which transistor has higher or lower Vth based on the favorite state (e.g. in FIG. 1, if SA_N2 has a lower threshold voltage than SA_N1, the favorite state will be SENSE=“1”, and SENSE_B=“0”). In some embodiments, in compensate mode, the wordline (WL_{COMPENSATE_MODE}) may be maintained to be 0V. A signal 1003 indicates the control signal SA_PRECH_B in normal mode (see FIG. 1; denoted by SA_PRECH_B) in the sense amplifier. A signal 1005 indicates the control signal SA_PRECH_B in compensate mode (see FIG. 1; denoted by SA_PRECH_B) in the sense amplifier. A signal 1004 indicates the control signal SA_SET (see FIG. 1) in the sense amplifier.

FIG. 10 shows a timing diagram illustrating a CTT programming scheme (e.g., transistor M2 in FIG. 7) in a sense amplifier (e.g., SA 700 in FIG. 7). In some embodiments, a CTT can be programmed using the existing PMOS transistor (PFET), e.g., transistor P1 or P2 in FIG. 7. When it is determined that the sense amplifier is put into compensate mode, all WLs may be disabled by maintaining the wordline signal WL_{COMPENSATE_MODE} to be 0V (see the signal 1002). Assuming Vth (M1)>Vth (M2), in some embodiments, a desirable state for programming M2 may be as follows: V_{G} (M1)<Vth (M1), V_{D} (M1)>1.5V, Vs (M1)=0V so that M1 is turned OFF and V_{DS} (M1)>1.5V. In this case, a desirable state for M2 may be as follows: V_{G} (M2)>1.5V, V_{D} (M2)<Vth (M1), Vs (M2)=0V so that M2 is turned ON and 0V<V_{DS} (M2)<Vth (M1). To achieve these desirable states, in some embodiments, while SA_SET is still ON, the precharge may be turned on by lowering the signal SA_PRECH_B_{COMPENSATE_MODE} at t₁₀₁ to create current through the device to be programmed (e.g., M2 in FIG. 7). It is noted that in a traditional design, SA_PRECH_B and SA_SET are non-overlapping (see SA_PRECH_B_{NORMAL_MODE} and SA_SET in FIG. 10) to avoid current burn. That is, typically, overlapping SA_PRECH_B and SA_SET may cause current burn. For example, in the traditional design, there is a period between a falling edge of SA_SET and a falling edge of SA_PRECH_B_{NORMAL_MODE} (e.g., the period 1006 in FIG. 10). In some embodiments, in compensate mode, SA_PRECH_B_{COMPENSATE_MODE} and SA_SET may be caused to be overlapping so as to intentionally create current burn, thereby using this current for increasing Vth of the low-Vth device (M2 in this case) during a programming phase (e.g., the period 1007 in FIG. 10). In other words, compensate mode can intentionally create current burn to program a CTT without adding any extra devices.

In some embodiments, before programming at least one CTT, a granularity of threshold voltage of transistors may be arbitrarily defined so that the threshold voltage of the at least one CTT may be changed with the defined granularity. In some embodiments, the threshold voltage of the at least one CTT may be changed in a non-volatile fashion (because the trapped charges will remain in the gate dielectric even after the chip is disconnected from a supply voltage/current) and in a multi-time programmable fashion (because charges can be trapped or removed multiple times). In some embodiments, a non-volatile SRAM (e.g., the SRAM 102 in FIG. 1) may be built to include a plurality of transistors. The plurality of transistors may include the at least one CTT (e.g., SRAM_N in FIG. 1). In building the non-volatile SRAM, an asymmetry (in terms of amount of trapped charges) may be added to a cell of the SRAM. The threshold voltage of the at least one CTT of the non-volatile SRAM may be increased or decreased. In some embodiments, the threshold voltage of the at least one CTT may be changed by increasing or decreasing the threshold voltage.

In some embodiments, the at least one CTT may be an NMOS transistor (e.g., M2 in FIG. 7). In changing the threshold voltage of the at least one CTT, a current may be passed or flow from a drain of the NMOS transistor to a source of the NMOS transistor. A positive voltage may be applied on a gate of the NMOS transistor such that electrons are trapped in the high-k gate dielectric so as to increase the threshold voltage of the NMOS transistor. In some embodiments, in changing the threshold voltage of the at least one CTT, a negative voltage may be applied on a gate of the NMOS transistor such that trapped electrons are removed from the high-k gate dielectric so as to decrease the threshold voltage of the NMOS transistor.

In some embodiments, the at least one CTT may be a PMOS transistor (e.g., M3 in FIG. 7). In changing the threshold voltage of the at least one CTT, a current may be passed or flow from a source of the PMOS transistor to a drain of the PMOS transistor. A negative voltage may be applied on a gate of the PMOS transistor such that holes are trapped in the high-k gate dielectric so as to increase the magnitude of the threshold voltage of the PMOS transistor. In some embodiments, in changing the threshold voltage of the at least one CTT, a positive voltage may be applied on a gate of the PMOS transistor such that trapped holes are removed from the high-k gate dielectric so as to decrease the magnitude of the threshold voltage of a PMOS transistor.

In some embodiments, the threshold voltage of the at least one CTT may be adjusted to mitigate at least one of (1) a negative impact of a process variation or mismatch (e.g., process variation in a differential sense amplifier may cause the amplifier to read data incorrectly), or (2) a temperature variation on performance of an integrated circuit.

In some embodiments, the threshold voltage of the at least one CTT may be adjusted to compensate for a mismatch of a pair of NMOS transistors or a pair of PMOS transistors in a sense amplifier (e.g., mismatch in threshold voltage between M1 and M2 in FIG. 7). In some embodiments, the threshold voltage of the at least one CTT may be adjusted to compensate for a mismatch of a pair of NMOS transistors or a pair of PMOS transistors in a bit cell of a static RAM (SRAM) (e.g., mismatch in threshold voltage between SRAM_N1 and SRAM_N2 in FIG. 1). In some embodiments, the threshold voltage of the at least one CTT may be adjusted to compensate for a mismatch of comparators in analog to digital convertors.

In some embodiments, the threshold voltage of the at least one CTT may be adjusted to obfuscate a circuit for hardware security. In some embodiments, the threshold voltage of the at least one CTT may be adjusted to increase or decrease a gain of an amplifier (e.g., the gain of the sense amplifier 700 in FIG. 7). The amplifier may use at least one of a common-source, a common-drain, a common-gate, or a cascode topology. For example, the sense amplifier 700 in FIG. 7 is a common-source amplifier. In some embodiments, the threshold voltage of the at least one CTT may be adjusted to increase or decrease a bandwidth of an amplifier.

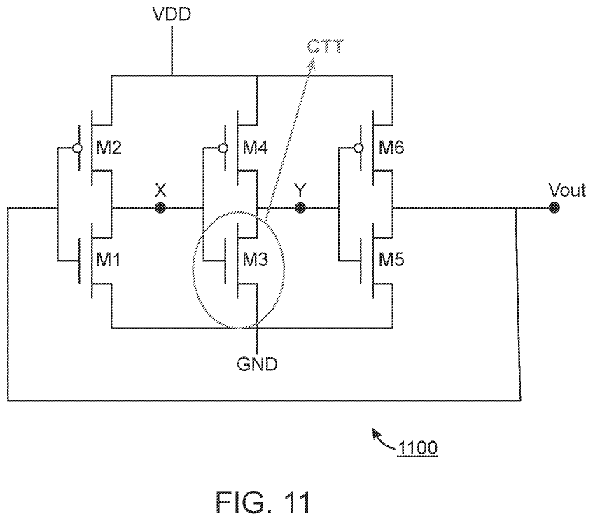

FIG. 11 is a circuit diagram illustrating an example ring oscillator with a charge trap transistor (CTT) according to some embodiments. Referring to FIG. 11, a ring oscillator 1100 may include PMOS transistors M2, M4, M6, whose sources are coupled to VDD, and NMOS transistors M1, M3, M5, whose sources are grounded. In some embodiments, M3 may be a CTT.

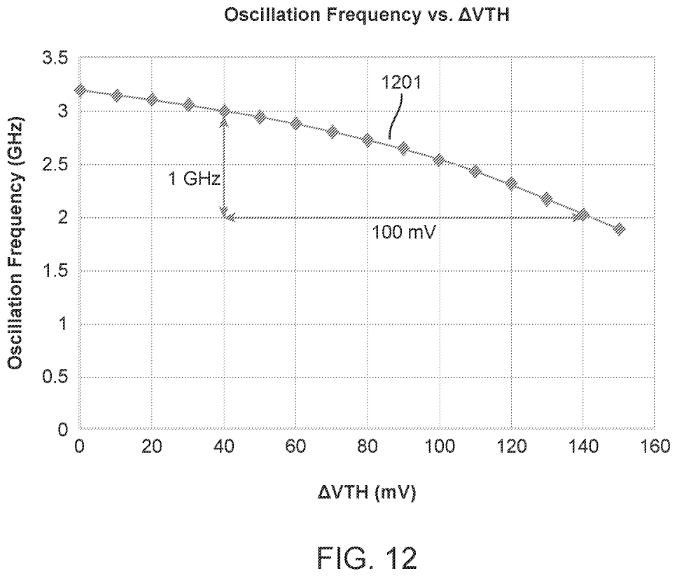

FIG. 12 is a diagram illustrating example values of oscillation frequencies as a result of changing threshold voltages using a CTT according to some embodiments. In some embodiments, the oscillation frequency of a ring oscillator (e.g., the ring oscillator 1100 in FIG. 11) may be fine-tuned using a CTT. In some embodiments, the oscillation frequency of a ring oscillator may be changed based on a relationship between oscillating frequency and a change of threshold voltage denoted by Δ(Vth), as shown in FIG. 12. For example, according to the relation shown in FIG. 12, the threshold voltage change of 100 mV can change the oscillation frequency by 1 GHz. In some embodiments, such relationship between oscillating frequency and threshold voltage change Δ(Vth) may be obtained based on equations below.

Vₜₕ=Vₜₕ₀+Δ(Vth) (Equation 3)

In some embodiments, the threshold voltage Vₜₕ of a transistor may be changed by trapping or de-trapping charge in a gate oxide of the transistor. In some embodiments, in a ring oscillator, changing Vₜₕ of a transistor in a NOT stage may vary its delay and consequently vary the frequency of the ring oscillator. Assuming that transistor M3 is a CTT (see FIG. 11), the drain current of M3 denoted by I_{D3} is given by:

$${I}_{D 3} = \frac{1}{2} {μ}_{n} {C}_{O X} \frac{{W}_{3}}{{L}_{3}} {( {V}_{X} - {V}_{t h 3} )}^{2} \qquad ( Equation 4 )$$

where, μₙ is electron mobility, C_{OX} is gate capacitance per unit area, L₃ and W₃ are gate length and gate width of M3 respectively, Vₓ is the voltage at node X (see FIG. 11), and Vₜₕ₃ is the threshold voltage of M3.

ΔT3 (i.e. falling delay of the 2^{nd} NOT stage in a ring oscillator) depends on Vₜₕ₃, due to the dependence of I_{D3} on Vₜₕ₃ according to Equation 4. ΔT3 is given by:

$$Δ T 3 = \frac{0.9 * VDD - 0.1 * VDD}{\overline{{I}_{D 3}} * {C}_{Y}} \qquad ( Equation 5 )$$

where I̅_̅{̅D̅3̅}̅ is an average current I_{D3} during falling transition at node Y (see FIG. 11), and C_{Y} is a total capacitance at node Y.

In some embodiments, the threshold voltage of the at least one CTT may be adjusted such that a delay of a clock tree or data paths is balanced to minimize a clock skew or correct hold-time violations. For example, using the above Equations 3-5, a delay of a clock tree or data paths can be balanced or changed to minimize a clock skew or correct hold-time violations.

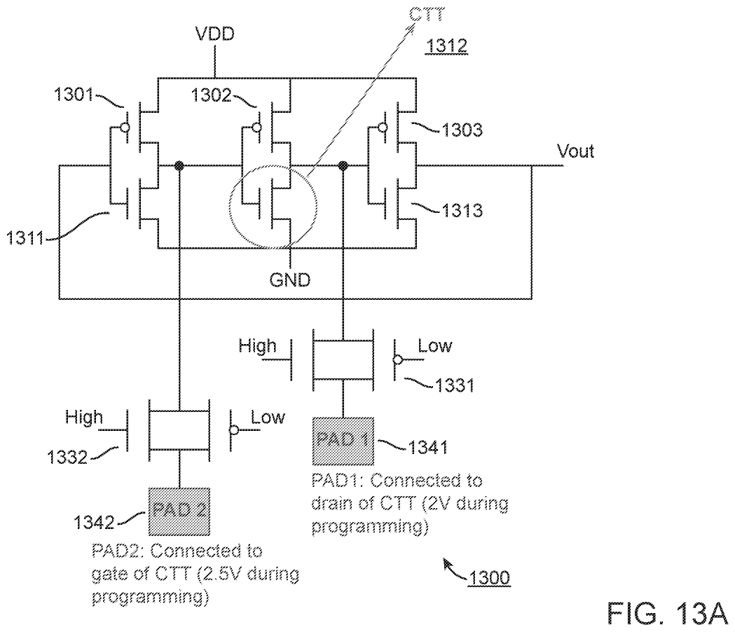

FIG. 13A is a circuit diagram illustrating an example ring oscillator with a CTT in a programming mode according to some embodiments. FIG. 13B is a circuit diagram illustrating an example ring oscillator with a CTT in an erase mode according to some embodiments. Referring to FIG. 13A and FIG. 13B, a ring oscillator 1300 may include PMOS transistors 1301, 1302, 1303, whose sources are coupled to VDD, and NMOS transistors 1311, 1312, 1313, whose sources are grounded. In some embodiments, the transistor 1312 may be a CTT. In some embodiments, a pad 1341 may be connected to a drain of the CTT via a transmission gate 1331, and a pad 1342 may be connected to a gate of the CTT via a transmission gate 1332.

Referring to FIG. 13A, in some embodiments, during a programming mode of the CTT of the ring oscillator 1300, by applying a voltage of 2V and a voltage of 2.5V to the pad 1341 and pad 1342, respectively, a high current may be passed through the CTT and charge may get trapped in a gate oxide of the CTT. In other words, for programming the CTT, V_{GS} (CTT)=2.5V and V_{DS} (CTT)=2V may be used. In some other embodiments, for programming the CTT, V_{GS} (CTT)=2V and V_{DS} (CTT)=1.5V may be used. In some embodiments, by trapping charge, Vth (CTT) can be increased and the oscillation frequency of the ring oscillator can be decreased.

Referring to FIG. 13B, in some embodiments, during an erase mode of the CTT of the ring oscillator 1300, by applying a voltage of 0V and a voltage of −2V to the pad 1341 and pad 1342, respectively, a large negative voltage may be applied to a gate of the CTT while V_{DS} (CTT)=0V. In some embodiments, V_{GS} (CTT)=−2V. This large negative voltage may remove trapped charges from the gate oxide of the CTT. In some embodiments, by removing (or de-trapping) trapped charges, Vth (CTT) can be reduced and the oscillation frequency of the ring oscillator can be increased accordingly.

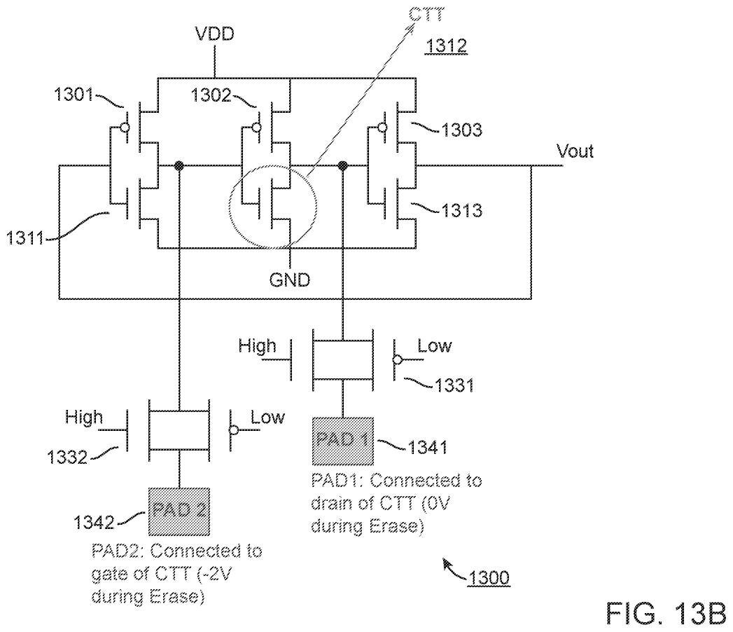

FIG. 14 is a circuit diagram illustrating another example ring oscillator with a CTT according to some embodiments. Referring to FIG. 14, a 3-stage ring oscillator 1400 may include PMOS transistors 1401, 1402, 1403, 1404, 1405, whose sources are coupled to VDD, and NMOS transistors 1411, 1412, 1413, 1414, 1415 whose sources are grounded. In some embodiments, the transistor 1412 may be a CTT. In some embodiments, a pad 1441 may be connected to a drain of the CTT via a transmission gate 1431, and a pad 1442 may be connected to a gate of the CTT via a transmission gate 1432. The PMOS transistors 1404, 1405 and the NMOS transistors 1414, 1415 may form an output buffer. The output buffer can be used to isolate the ring oscillator from the load. Post layout simulation shows an oscillation frequency of 3.2 GHz with VDD=800 mV before programming. In some embodiments, during a programming mode of the ring oscillator 1400, a voltage of 2V and a voltage of 2.5V can be applied to the pad 1441 and the pad 1442, respectively. As shown in FIG. 14, all transistors (1401, 1402, 1403, 1404, 1405, 1411, 1412, 1413, 1414, 1415, 1421) have the same length, e.g., 20 nm. The PMOS transistors 1401, 1402, 1403 have the same width of 1.3 μm, while the PMOS transistor 1421 has the width of 3 μm, the PMOS transistor 1404 has the width of 2 μm, and the PMOS transistor 1405 has the width of 4.6 μm. The NMOS transistors 1411, 1412, 1413 have the same width of 0.65 μm, while the NMOS transistor 1414 has the width of 1 μm and the NMOS transistor 1415 has the width of 2.3 μm.

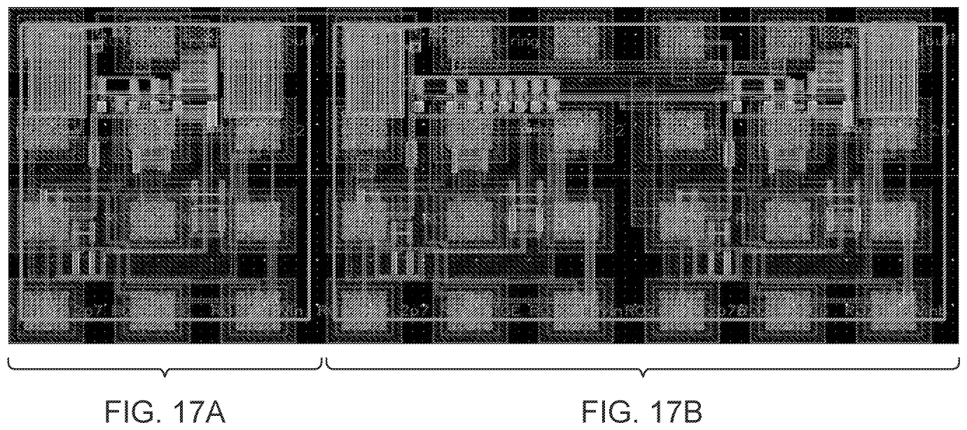

FIG. 15 is a circuit diagram illustrating an example ring oscillator with multiple CTTs according to some embodiments. Referring to FIG. 15, an 11-stage ring oscillator 1500 may include a core (ring) 1510, a 2-stage output buffer 1520, and two Vth-programing circuits 1550 and 1560. The core 1510 includes 11 PMOS transistors, whose sources are coupled to VDD (VDD-RING), and 11 NMOS transistors whose sources are grounded. The 2-stage buffer is designed to provide sufficient drive to an external load. The output buffer 1520 includes 2 PMOS transistors, whose sources are coupled to VDD (VDD-Buffer), and 2 NMOS transistors whose sources are grounded. In some embodiments, the core 1510 may include a first CTT (e.g., “CTT-1” which is the second NMOS from the left in FIG. 15) and a second CTT (e.g., “CTT-2” which is the second NMOS from the right in FIG. 15). In some embodiments, in the Vth-programing circuits 1550, a pad 1541 may be connected to a drain of the first CTT via a transmission gate (T-GATE) 1531, and a pad 1542 may be connected to a gate of the first CTT via a transmission gate (T-GATE) 1532. Similarly, in the Vth-programing circuits 1560, a pad 1543 may be connected to a drain of the second CTT via a transmission gate (T-GATE) 1533, and a pad 1544 may be connected to a gate of the second CTT via a transmission gate (T-GATE) 1534. In other words, the transmission gates 1532, 1534 may be used for setting the gate voltages of the first and second CTT, respectively, and the transmission gates 1531, 1533 may be used for setting the drain voltages of the first and second CTT, respectively. FIG. 15 shows that the ring oscillator 1500 has four pads, but embodiments of the present disclosure are not limited thereto. For example, a chip layout in FIG. 17A and FIG. 17B has 36 total pads (shown as 36 small squares), which include 12 pads in a ring oscillator in FIG. 17A and 24 pads in a ring oscillator in FIG. 17B.

In some embodiments, during a programming mode of the ring oscillator 1500, a voltage of 2V and a voltage of 2.5V can be applied to the pad 1541 and the pad 1542, respectively, and a voltage of 2V and a voltage of 2.5V can be applied to the pad 1543 and the pad 1544, respectively. In some embodiments, the gate width of each of PMOS transistors in the core 1510 is 1.3 μm and the gate width of each of NMOS transistors in the core 1510 is 0.65 μm. In some embodiments, the gate widths of the two PMOS transistors in the output buffer 1520 are 2 μm and 4.6 μm, respectively, and the gate widths of the two NMOS transistors in the output buffer 1520 are 1 μm and 2.3 μm, respectively. In some embodiments, all the transistors shown in FIG. 15 have a length of 20 nm.

In some embodiments, the threshold voltage of the at least one CTT may be adjusted to increase or decrease an oscillation frequency of an oscillator. The oscillator may be a ring oscillator (e.g., the ring oscillators 1300, 1400, 1500 in FIG. 13A to FIG. 15) or a cross-coupled oscillator.

In an experiment according to some embodiments, the output of the output buffer (e.g., output buffer 1520 in FIG. 15) is connected to a spectrum analyzer to measure the frequency of the ring oscillator. In some embodiments, the ring (e.g., ring 1510 in FIG. 15) and the output buffer use thin-oxide transistors, while transmission gates (T-GATES 1550, 1560 in FIG. 15) are fabricated using thick-oxide transistors to handle a large external voltage during programming. The frequency of a ring oscillator depends on the delay of each stage, T_{D}, and the number of stages, N, according to the following equation:

$$f = \frac{1}{2 N {T}_{D}} \qquad ( Equation 6 )$$

T_{D} rises as V_{TH} of the NMOS transistor increases. In some embodiments, by trapping charge in the high-k gate oxide of the CTT NMOS, the delay of the NMOS can be increased and the oscillation frequency of the ring oscillator can be reduced, in a controllable and reliable manner.

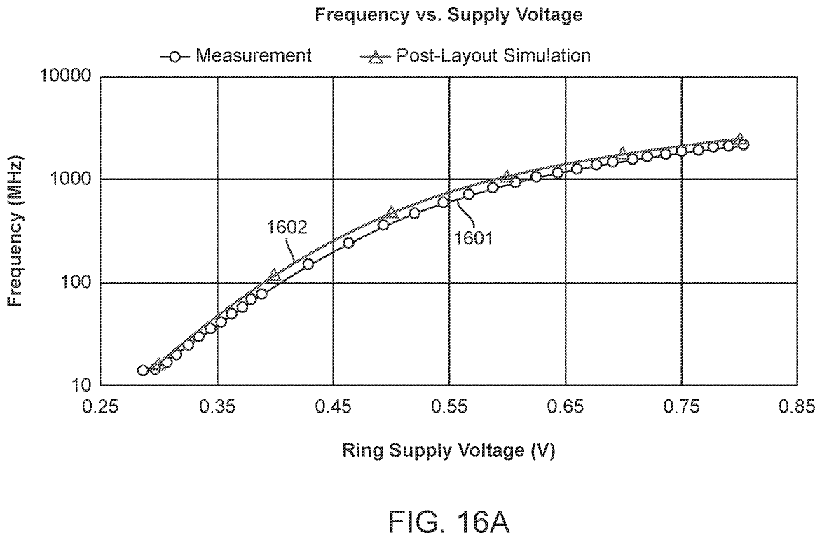

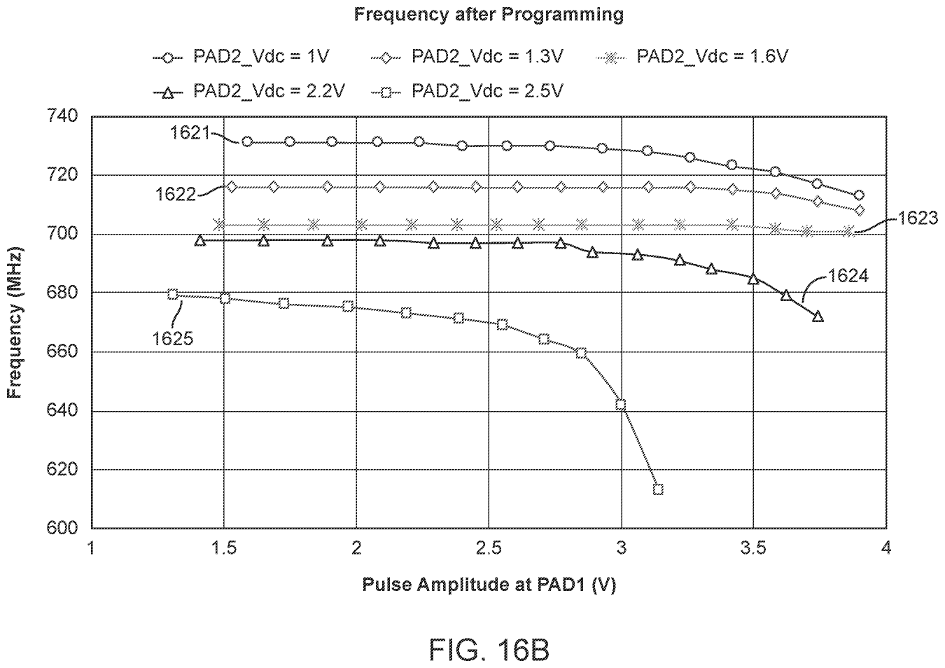

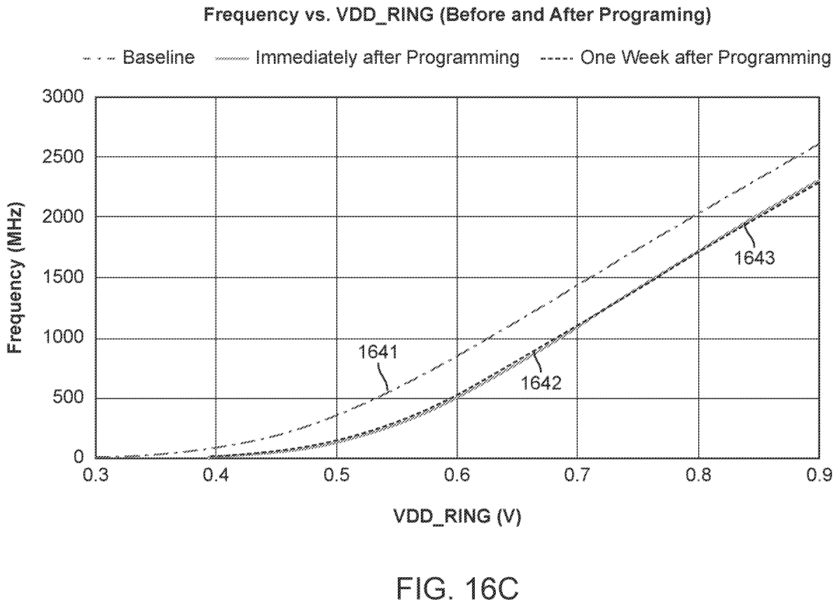

FIG. 16A, FIG. 16B and FIG. 16C show measurement results using an example ring oscillator with CTTs according to some embodiments, which demonstrate the performance of the ring oscillator when performing non-volatile frequency tuning of the ring oscillator.

In an experiment according to some embodiments, a spectrum analyzer Keysight™ PXA N9030A may be used to measure the output spectrum of a chip. The macro (physical design) of 57 μm×36 μm was designed and used in the experiment. If a conventional C4 bump/pillar technology is used, the pad area (e.g., pads 1541-1544 in FIG. 15) consumed would be 30×100×100 μm² or 150 times the area of the macro. In some embodiments, an advanced packaging technique called the silicon interconnect fabric (Si IF) may be used to attach these dies using Cu—Cu thermal compression bonding at 10 μm pitch (vs. 100 μm pitch). A probe card may be used to probe the pads on the Si IF platform.

FIG. 16A shows the frequency of the ring oscillator as a function of supply voltage in both simulation (line 1602) and measurement (line 1601) that match closely. In some embodiments, based on the measurement results, the 11-stage ring oscillator (e.g., ring oscillator shown in FIG. 15) may be configured to start to oscillate at VDD=0.29V. At this voltage, the oscillation frequency may be 13.66 MHz and the oscillator may consume 0.12 μM. By increasing the supply voltage, the frequency may increase to 2.165 GHz at VDD=0.8V and the power consumption may rise to 169.2 μM.

FIG. 16B is a diagram illustrating an example of effects of charge trapping on oscillation frequency in an example ring oscillator with CTTs according to some embodiments.

In order to demonstrate the impact of the trapping electrons in the high-k gate dielectric of the CTT, in an experiment according to some embodiments, voltage pulses have been applied at a pad connected to the gate of a CTT (referred to as “PAD1”; e.g., pads 1542 and 1544 in FIG. 15). In each programming attempt, 300 pulses have been applied over 30 sec with pulse rate of 10 Hz at PAD1. The duration of each pulse was set to about 100 μsec. FIG. 16B shows the impact of programming voltage levels (i.e. V_{GS} and V_{DS} of the CTT) on the frequency shift. In FIG. 16B, X-axis shows the voltage levels at PAD1, which varies from 1.3V to 3.9V. Each curve in FIG. 16B corresponds to a different DC voltage level applied at a pad connected to the drain of a CTT (referred to as “PAD2”; e.g., pads 1541 and 1543 in FIG. 15). These voltage values at PAD2 are 1V, 1.3V, 1.6V, 2.2V, and 2.5V which correspond to lines 1621, 1622, 1623, 1624, and 1625, respectively, in FIG. 16B. It is noted that due to the voltage drop on the T-GATEs, the actual voltages reached to the CTT gate and drain are smaller than the voltages applied at PAD1 and PAD2, respectively.

In an experiment according to some embodiments, after every programming attempt, the programming circuitry was disabled, VDD-RING was set to 570 mV, and frequency of the ring oscillator was re-measured. As shown in FIG. 16B, it was observed that by increasing the amplitude of the pulses applied at PAD1, more electrons are trapped in the high-k HfOx dielectric and threshold voltage of the NMOS is increased, as expected. Also, by increasing the voltage applied at PAD2 and passing higher IDS, the self-heating is increased, thereby assisting the charge trapping process. The increased self-heating can create a larger V_{TH} shift and further reduce the oscillation frequency.

FIG. 16C is a diagram illustrating example oscillation frequency values as a function of VDD RING (see FIG. 15) before and after programming an example ring oscillator with CTTs according to some embodiments.

In an experiment according to some embodiments as another programming method, the programming circuitry was disabled and the ring oscillator was programmed by raising its supply voltage (VDD-RING). In this experiment, a baseline was produced by measuring the ring oscillator frequency as a function of VDD-RING (line 1641 in FIG. 16C). Then, a large voltage of 2.3V was applied to VDD-RING for about 3 seconds to program the ring oscillator transistors. Immediately after programming with the elevated VDD-RING, the frequency of the ring oscillator was measured as a function of VDD-RING again (line 1642 in FIG. 16C). It is observed that the stress induced by a high voltage of VDD-RING=2.3V caused trapping of electrons in the gate dielectric, which increased V_{TH} of transistors and reduced frequency of the ring oscillator.

As shown in FIG. 16C, at VDD-RING=0.8V, the frequency of the ring oscillator were changed from 2075 GHz (see line 1641) to 1746 GHz (see line 1642), resulting in the frequency-shift of 329 MHz. Based on the Monte Carlo analysis, one-sigma frequency variation due to the process variation and mismatch is 119 MHz at VDD-RING=0.8V. Therefore, the programming technique according to some embodiments can cover a tuning range of 2.8-sigma at VDD-RING=0.8V. In this experiment, the oscillation frequency decreased by 16% at VDD-RING=0.8V. Based on the post-layout simulation in Cadence® Virtuoso®, to reduce the oscillation frequency by 16% at VDD-RING=0.8V, the V_{TH} of NMOS transistors should increase by 110 mV. According to the transient simulation, at VDD-RING=2.3V, about 1% of the time in every cycle, both V_{DS} and V_{GS} are higher than 1.5V. This level of V_{DS} and V_{GS} is desired to create deep traps. This means the actual programming happens during only 1% of the time that the elevated VDD-RING is applied.

In this experiment, the measured DC current of the oscillator (drawn from VDD-RING in FIG. 15) increases from 0.19 mA at VDD-RING=0.8V (during normal operation) to 2.5 mA at VDD-RING=2.3V (during programming). The 2.5 mA during programming corresponds to about 227 μA per stage.

To study the stability of the frequency shift, this measurement was repeated after a week and reported the results in FIG. 16C (see line 1643). As shown in FIG. 16C, the frequency shift remains very stable. It is also shown that self-heating assisted trapping fills deep oxygen vacancies in HfOx that lasts over 10 years.

Table 1 as shown below compares different V_{TH} tuning methods along with the demonstrated hardware.

TABLE 1
Comparison of Different V_{TH} Tuning Methods

| | Freq. Tuning | Non- | | |
|---|---|---|---|---|
| | Range | Vol- | | Demonstrated |
| Method | (MHz) | atile | Node | Hardware |
| CTT PRG | 1746-2075 | Yes | 22 nm FDSOI | Oscillator Tuning |
| | N/A | Yes | 22 nm FDSOI | Analog Memory Cell |
| | N/A | Yes | 22 nm FDSOI | Digital Memory Array |
| | N/A | Yes | 14 nm FinFET | Digital Memory Array |
| | 377-556 | No | 65 nm CMOS | Oscillator Tuning |
| Back- | 25300-26300 | No | 22 nm FDSOI | Oscillator Tuning |
| gate/Body | | | | |
| Biasing | | | | |

As described above, embodiments of the present disclosure provide a non-volatile technique for tuning the frequency of a GHz ring oscillator using self-heating assisted charge trapping in high-k gate dielectric of advanced CMOS nodes.

FIG. 17A and FIG. 17B illustrate an example chip layouts of two ring oscillators with different number of stages according to some embodiments. FIG. 17A shows a 3-stage ring oscillator with dimension of 27 μm (W)×36 μm (L), while FIG. 17B shows a 11-stage ring oscillator with dimension of 57 μm (W)×36 μm (L).

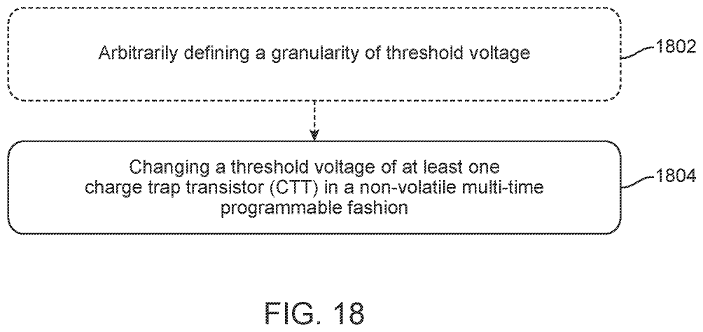

FIG. 18 is a flowchart illustrating an example methodology for changing functionality of an integrated circuit or improving performance of an integrated circuit using charge trap transistors (CTTs), according to some embodiments.

In this example, the process may begin in step S1802 by arbitrarily defining a granularity of threshold voltage of transistors of an integrated circuit.

In step S1804, in some embodiments, a threshold voltage of at least one charge trap transistor (CTT) may be changed in a non-volatile multi-time programmable fashion. The at least one CTT may be fabricated using a high-k dielectric material as a gate dielectric. In some embodiments, the at least one CTT may be at least one of NMOS transistor or PMOS transistor. The at least one of NMOS transistor or PMOS transistor is fabricated using a high-k dielectric material as a gate dielectric. In some embodiments, the threshold voltage of the at least one CTT may be changed with the granularity defined in step S1802. In some embodiments, the threshold voltage of the at least one CTT may be changed by increasing or decreasing the threshold voltage.

In some embodiments, the at least one CTT may be an NMOS transistor. In changing the threshold voltage of the at least one CTT, a current may be passed or flow from a drain of the NMOS transistor to a source of the NMOS transistor. A positive voltage may be applied on a gate of the NMOS transistor such that electrons are trapped in the high-k gate dielectric so as to increase the threshold voltage of the NMOS transistor. In some embodiments, in changing the threshold voltage of the at least one CTT, a negative voltage may be applied on a gate of the NMOS transistor such that trapped electrons are removed from the high-k gate dielectric so as to decrease the threshold voltage of the NMOS transistor.

In some embodiments, the at least one CTT may be a PMOS transistor. In changing the threshold voltage of the at least one CTT, a current may be passed or flow from a source of the PMOS transistor to a drain of the PMOS transistor. A negative voltage may be applied on a gate of the PMOS transistor such that holes are trapped in the high-k gate dielectric so as to increase a magnitude of the threshold voltage of the PMOS transistor. In some embodiments, in changing the threshold voltage of the at least one CTT, a positive voltage may be applied on a gate of the PMOS transistor such that trapped holes are removed from the high-k gate dielectric so as to decrease a magnitude of the threshold voltage of a PMOS transistor.

In some embodiments, a method for changing functionality of an integrated circuit including at least one CTT may include adjusting or changing the threshold voltage of the at least one CTT to mitigate at least one of (1) a negative impact of a process variation, (2) a mismatch or (3) a temperature variation on performance of the integrated circuit.

In some embodiments, a method for changing functionality of a sense amplifier including at least one CTT may include adjusting or changing the threshold voltage of the at least one CTT to compensate for a mismatch of a pair of NMOS transistors or a pair of PMOS transistors in the sense amplifier.

In some embodiments, a method for changing functionality of a static RAM (SRAM) including at least one CTT may include adjusting or changing the threshold voltage of the at least one CTT to compensate for a mismatch of a pair of NMOS transistors or a pair of PMOS transistors in a bit cell of the SRAM.

In some embodiments, a method for changing functionality of analog to digital convertors (ADCs) including at least one CTT may include adjusting or changing the threshold voltage of the at least one CTT to compensate for a mismatch of comparators in the ADCs.

In some embodiments, a method for changing functionality of a system including at least one CTT may include adjusting or changing the threshold voltage of the at least one CTT such that a delay of a clock tree or data paths is balanced to minimize a clock skew or correct hold-time violations in the system.

In some embodiments, a method for changing functionality of a circuit for hardware security including at least one CTT may include adjusting or changing the threshold voltage of the at least one CTT to obfuscate the circuit for hardware security.

In some embodiments, a method for changing functionality of an amplifier including at least one CTT may include adjusting or changing the threshold voltage of the at least one CTT to increase or decrease a gain of the amplifier. The amplifier may use at least one of a common-source, a common-drain, a common-gate, or a cascode topology.

In some embodiments, a method for changing functionality of an amplifier including at least one CTT may include adjusting or changing the threshold voltage of the at least one CTT to increase or decrease a bandwidth of the amplifier.

In some embodiments, a method for changing functionality of an oscillator including at least one CTT may include adjusting or changing the threshold voltage of the at least one CTT to increase or decrease an oscillation frequency of the oscillator. The oscillator may be a ring oscillator or a cross-coupled oscillator.

In some embodiments, a method for manufacturing a non-volatile SRAM may include building a non-volatile SRAM to include a plurality of transistors. The plurality of transistors may include the at least one CTT. The method may include increasing or decreasing the threshold voltage of the at least one CTT of the non-volatile SRAM such that an asymmetry is added to a cell of the SRAM.

In some embodiments, the change in threshold voltage of a CTT transistor is non-volatile and/or multi-time programmable, such that the non-volatile change in the threshold voltage can be set to last for a predetermined duration of time (e.g. 1 msec, 1 second, 1 day, 1 year, 10 years, or longer). In some embodiments, the duration of the non-volatility (i.e. the stability of the trapped charges) can be modulated by transistor biasing conditions during CTT programming. In some embodiments, programming an NMOS with a higher VGS and a higher VDS for a longer duration, results in a deeper and more stable trapped charges, and non-volatility to last for a longer time (e.g. programming an NMOS with VGS=2V, VDS=2V, for duration of 10 msec results in a longer lasting Vth change than that of programming an NMOS with VGS=1.5V, VDS=0.2V, for duration of 1 usec).

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout the previous description that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is understood that the specific order or hierarchy of steps in the processes disclosed is an example of illustrative approaches. Based upon design preferences, it is understood that the specific order or hierarchy of steps in the processes may be rearranged while remaining within the scope of the previous description. The accompanying method claims present elements of the various steps in a sample order, and are not meant to be limited to the specific order or hierarchy presented.

The previous description of the disclosed implementations is provided to enable any person skilled in the art to make or use the disclosed subject matter. Various modifications to these implementations will be readily apparent to those skilled in the art, and the generic principles defined herein may be applied to other implementations without departing from the spirit or scope of the previous description. Thus, the previous description is not intended to be limited to the implementations shown herein but is to be accorded the widest scope consistent with the principles and novel features disclosed herein.

The various examples illustrated and described are provided merely as examples to illustrate various features of the claims. However, features shown and described with respect to any given example are not necessarily limited to the associated example and may be used or combined with other examples that are shown and described. Further, the claims are not intended to be limited by any one example.

The foregoing method descriptions and the process flow diagrams are provided merely as illustrative examples and are not intended to require or imply that the steps of various examples must be performed in the order presented. As will be appreciated by one of skill in the art the order of steps in the foregoing examples may be performed in any order. Words such as “thereafter,” “then,” “next,” etc. are not intended to limit the order of the steps; these words are simply used to guide the reader through the description of the methods. Further, any reference to claim elements in the singular, for example, using the articles “a,” “an” or “the” is not to be construed as limiting the element to the singular.

The various illustrative logical blocks, modules, circuits, and algorithm steps described in connection with the examples disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The hardware used to implement the various illustrative logics, logical blocks, modules, and circuits described in connection with the examples disclosed herein may be implemented or performed with a general purpose processor, a DSP, an ASIC, an FPGA or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Alternatively, some steps or methods may be performed by circuitry that is specific to a given function.

In some exemplary examples, the functions described may be implemented in hardware, software, firmware, or any combination thereof. If implemented in software, the functions may be stored as one or more instructions or code on a non-transitory computer-readable storage medium or non-transitory processor-readable storage medium. The steps of a method or algorithm disclosed herein may be embodied in a processor-executable software module which may reside on a non-transitory computer-readable or processor-readable storage medium. Non-transitory computer-readable or processor-readable storage media may be any storage media that may be accessed by a computer or a processor. By way of example but not limitation, such non-transitory computer-readable or processor-readable storage media may include RAM, ROM, EEPROM, FLASH memory, CD-ROM or other optical disk storage, magnetic disk storage or other magnetic storage devices, or any other medium that may be used to store desired program code in the form of instructions or data structures and that may be accessed by a computer. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above are also included within the scope of non-transitory computer-readable and processor-readable media. Additionally, the operations of a method or algorithm may reside as one or any combination or set of codes and/or instructions on a non-transitory processor-readable storage medium and/or computer-readable storage medium, which may be incorporated into a computer program product.

The preceding description of the disclosed examples is provided to enable any person skilled in the art to make or use the present disclosure. Various modifications to these examples will be readily apparent to those skilled in the art, and the generic principles defined herein may be applied to some examples without departing from the spirit or scope of the disclosure. Thus, the present disclosure is not intended to be limited to the examples shown herein but is to be accorded the widest scope consistent with the following claims and the principles and novel features disclosed herein.

1. A method for changing functionality of an integrated circuit or improving performance of an integrated circuit, the method comprising:
changing a threshold voltage of at least one charge trap transistor (CTT),
wherein the at least one CTT is fabricated using a high-k dielectric material as a gate dielectric.

2. The method of claim 1, wherein the change in the threshold voltage is non-volatile and/or multi-time programmable.

3. The method of claim 2, wherein a duration of the non-volatile change in the threshold voltage is set to a predetermined duration of time.

4. The method of claim 3, wherein the predetermined duration of time is 1 msec, 1 second, 1 day, 1 year, 10 years, or longer than 10 years.

5. The method of claim 3, wherein the duration of the non-volatility is modulated by transistor biasing conditions during CTT programming.

6. The method of claim 1, wherein changing the threshold voltage of the at least one CTT comprises increasing or decreasing the threshold voltage.

7. The method of claim 1, further comprising:
arbitrarily defining a granularity of threshold voltage,
wherein the threshold voltage of the at least one CTT is changed with the defined granularity.

8. The method of claim 1, wherein the at least one CTT is at least one of NMOS transistor or PMOS.

9. The method of claim 8, wherein
the at least one CTT is an NMOS transistor, and
changing the threshold voltage of the at least one CTT comprises
passing a current from a drain of the NMOS transistor to a source of the NMOS transistor, and
applying a positive voltage on a gate of the NMOS transistor such that electrons are trapped in the high-k gate dielectric so as to increase the threshold voltage of the NMOS transistor.

10. The method of claim 8, wherein
the at least one CTT is an NMOS transistor, and
changing the threshold voltage of the at least one CTT comprises
applying a negative voltage on a gate of the NMOS transistor such that trapped electrons are removed from the high-k gate dielectric so as to decrease the threshold voltage of the NMOS transistor.

11. The method of claim 8, wherein
the at least one CTT is a PMOS transistor, and
changing the threshold voltage of the at least one CTT comprises
passing a current from a source of the PMOS transistor to a drain of the PMOS transistor, and
applying a negative voltage on a gate of the PMOS transistor such that holes are trapped in the high-k gate dielectric so as to increase a magnitude of the threshold voltage of the PMOS transistor.

12. The method of claim 8, wherein
the at least one CTT is a PMOS transistor, and
changing the threshold voltage of the at least one CTT comprises
applying a positive voltage on a gate of the PMOS transistor such that trapped holes are removed from the high-k gate dielectric so as to decrease a magnitude of the threshold voltage of a PMOS transistor.

13. A method for changing functionality of an integrated circuit including at least one charge trap transistor (CTT), comprising:
changing a threshold voltage of the at least one CTT according to the method as recited in claim 1,
wherein the threshold voltage of the at least one CTT is changed to mitigate at least one of (1) a negative impact of a process variation, (2) a mismatch or (3) a temperature variation on performance of the integrated circuit.

14. A method for changing functionality of a sense amplifier including at least one charge trap transistor (CTT), comprising:
changing a threshold voltage of the at least one CTT according to the method as recited in claim 1,
wherein the threshold voltage of the at least one CTT is changed to compensate for a mismatch of a pair of NMOS transistors or a pair of PMOS transistors in the sense amplifier.

15. A method for changing functionality of a static RAM (SRAM) including at least one charge trap transistor (CTT), comprising:
changing a threshold voltage of the at least one CTT according to the method as recited in claim 1,
wherein the threshold voltage of the at least one CTT is changed to compensate for a mismatch of a pair of NMOS transistors or a pair of PMOS transistors in a bit cell of the static RAM (SRAM).

16. A method for changing functionality of analog to digital convertors (ADCs) including at least one charge trap transistor (CTT), comprising:
changing a threshold voltage of the at least one CTT according to the method as recited in claim 1,
wherein the threshold voltage of the at least one CTT is changed to compensate for a mismatch of comparators in the ADCs.

17. A method for changing functionality of a system including at least one charge trap transistor (CTT), comprising:
changing a threshold voltage of the at least one CTT according to the method as recited in claim 1,
wherein the threshold voltage of the at least one CTT is changed such that a delay of a clock tree or data paths is balanced to minimize a clock skew or correct hold-time violations in the system.

18. A method for changing functionality of a circuit for hardware security including at least one charge trap transistor (CTT), comprising:
changing a threshold voltage of the at least one CTT according to the method as recited in claim 1,
wherein the threshold voltage of the at least one CTT is changed to obfuscate a circuit for hardware security.

19. A method for changing functionality of an amplifier including at least one charge trap transistor (CTT), comprising:
changing a threshold voltage of the at least one CTT according to the method as recited in claim 1,
wherein the threshold voltage of the at least one CTT is changed to increase or decrease a gain of an amplifier.

20. The method of claim 19, wherein the amplifier uses at least one of a common-source, a common-drain, a common-gate, or a cascode topology.

21. A method for changing functionality of an amplifier including at least one charge trap transistor (CTT), comprising:
changing a threshold voltage of the at least one CTT according to the method as recited in claim 1,
wherein the threshold voltage of the at least one CTT is changed to increase or decrease a bandwidth of the amplifier.

22. A method for changing functionality of an oscillator including at least one charge trap transistor (CTT), comprising:
changing a threshold voltage of the at least one CTT according to the method as recited in claim 1,
wherein the threshold voltage of the at least one CTT is changed to increase or decrease an oscillation frequency of the oscillator.

23. The method of claim 22, wherein the oscillator is a ring oscillator or a cross-coupled oscillator.

24. A method for manufacturing a non-volatile SRAM, comprising:
building a non-volatile SRAM to include a plurality of transistors, the plurality of transistors including at least one charge trap transistor (CTT); and
changing a threshold voltage of the at least one CTT according to the method as recited in claim 1,
wherein the threshold voltage of the at least one CTT is increased or decreased such that an asymmetry is added to a cell of the SRAM.

25. A method for suppressing security exposure of a circuit block, the method comprising:
after integrating the circuit block into a system, changing a threshold voltage of at least one charge trap transistor (CTT) of the circuit block,
wherein the at least one CTT is fabricated using a high-k dielectric material as a gate dielectric.

26. The method of claim 25, wherein the circuit block comprises one or more circuits, one or more ICs, one or more IC chips, one or more IP (intellectual property) blocks, or one or more electric devices.

27. The method of claim 25, wherein the threshold voltage of the at least one CTT is changed so that the circuit block after changing the threshold voltage performs a function different from a function performed by the circuit block before changing the threshold voltage.

28. The method of claim 25, wherein the threshold voltage of the at least one CTT is changed so that the circuit block after changing the threshold voltage performs a function different from a function performed by the circuit block at an initial test of the circuit block.

29. The method of claim 25, wherein
the system comprises a plurality of electric devices, and
changing the threshold voltage of the at least one CTT comprises changing threshold voltages of CTTs of one or more electric devices of the plurality of electric devices.
